(19) United States
(12) Patent Application Publication
(10) Pub. No.: US 2026/0303025 A1
(43) Pub. Date: Oct. 1, 2026

(54) POWER COMBINED POWER AMPLIFIER

(71) Applicant: QUALCOMM Incorporated, San Diego, CA (US)

(72) Inventors: Paolo Enrico DE FALCO, San Diego, CA (US); Hakan INANOGLU, Acton, MA (US); Antonino SCUDERI, San Diego, CA (US)

(21) Appl. No.: 19/090,881

(22) Filed: Mar. 26, 2025

(51) Int. Cl. H03F 1/02; H03F 3/24

(52) U.S. Cl. CPC H03F 1/0288; H03F 3/245; H03F 2200/451

(57) ABSTRACT

A system includes a first amplifier, a second amplifier, and a first output hybrid coupler, wherein a first port of the first output hybrid coupler is coupled to an output of the first amplifier, and a second port of the first output hybrid coupler is coupled to an output of the second amplifier. The system also includes a third amplifier, a fourth amplifier, and a second output hybrid coupler, wherein a first port of the second output hybrid coupler is coupled to an output of the third amplifier, and a second port of the second output hybrid coupler is coupled to an output of the fourth amplifier. The system further includes a switching network coupled between the first output hybrid coupler and the second output hybrid coupler.

### BACKGROUND

### Field

Aspects of the present disclosure relate generally to wireless communications, and, more particularly, to power amplifiers.

### Background

A wireless device includes a transmitter for transmitting radio frequency (RF) signals via one or more antennas. The transmitter may include power amplifiers for amplifying the RF signals before transmission.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a system. The system includes a first amplifier, a second amplifier, and a first output hybrid coupler having a first port, a second port, a third port, and a fourth port, wherein the first port of the first output hybrid coupler is coupled to an output of the first amplifier, and the second port of the first output hybrid coupler is coupled to an output of the second amplifier. The system also includes a third amplifier, a fourth amplifier, and a second output hybrid coupler having a first port, a second port, a third port, and a fourth port, wherein the first port of the second output hybrid coupler is coupled to an output of the third amplifier, and the second port of the second output hybrid coupler is coupled to an output of the fourth amplifier. The system further includes a switching network coupled between the fourth port of the first output hybrid coupler and the third port of the second output hybrid coupler.

A second aspect relates to a system. The system includes a transmit circuit, a first amplifier, a second amplifier, a first input hybrid coupler having a first port, a second port, a third port, and a fourth port, wherein the third port of the first input hybrid coupler is coupled to an input of the first amplifier, and the fourth port of the first input hybrid coupler is coupled to an input of the second amplifier, and a first input switching network coupled to the transmit circuit, the first port of the first input hybrid coupler, and the second port of the first input hybrid coupler, wherein the first input switching network is configured to selectively couple the transmit circuit to the first port of the first input hybrid coupler or the second port of the first input hybrid coupler. The system also includes a third amplifier, a fourth amplifier, a second input hybrid coupler having a first port, a second port, a third port, and a fourth port, wherein the third port of the second input hybrid coupler is coupled to an input of the third amplifier, and the fourth port of the second input hybrid coupler is coupled to an input of the fourth amplifier, and a second input switching network coupled to the transmit circuit, the first port of the second input hybrid coupler, and the second port of the second input hybrid coupler, wherein the second input switching network is configured to selectively couple the transmit circuit to the first port of the second input hybrid coupler or the second port of the second input hybrid coupler.

A third aspect relates to a method for wireless communications in a system. The system includes a first amplifier, a second amplifier, a first output hybrid coupler having a first port coupled to an output of the first amplifier and a second port coupled to an output of the second amplifier, a third amplifier, a fourth amplifier, and a second output hybrid coupler having a first port coupled to an output of the third amplifier and a second port coupled to an output of the fourth amplifier. The method includes, in a first configuration, coupling a third port of the first output hybrid coupler to a first antenna, coupling a fourth port of the first output hybrid coupler to a first termination load or a ground, coupling a third port of the second output hybrid coupler to a second antenna, and coupling a fourth port of the second output hybrid coupler to a second termination load or the ground. The method also includes, in a second configuration, coupling the third port of the first output hybrid coupler to the first antenna or the second antenna, and coupling the third port of the second output hybrid coupler to the fourth port of the first output hybrid coupler.

A fourth aspect relates to a method for wireless communications in a system. The system includes a first amplifier, a second amplifier, a first input hybrid coupler having a first port, a second port, a third port coupled to an input of the first amplifier, and a fourth port coupled to an input of the second amplifier, a third amplifier, a fourth amplifier, and a second input hybrid coupler having a first port, a second port, a third port coupled to an input of the third amplifier, and a fourth port coupled to an input of the fourth amplifier. The method include, in a first configuration, inputting a first radio frequency (RF) signal to the first port of the first input hybrid coupler, coupling the second port of the first input hybrid coupler to a first termination load, inputting a second input RF signal to the first port of the second input hybrid coupler, and coupling the second port of the second input hybrid coupler to a second termination load. The method also includes in a second configuration, inputting the first RF signal to the second port of the first input hybrid coupler, coupling the first port of the first input hybrid coupler to the first termination load, inputting the second input RF signal to the second port of the second input hybrid coupler, and coupling the first port of the second input hybrid coupler to the second termination load.

### BRIEF DESCRIPTION OF THE DRAWINGS

FIG. 1A shows an example in which a single power amplifier and a single antenna are used to transmit a data stream according to certain aspects of the present disclosure.

FIG. 1B shows an example in which multiple power amplifiers and multiple antennas are used to transmit independent data streams according to certain aspects of the present disclosure.

FIG. 1C shows an example in which multiple power amplifiers and multiple antennas are used to transmit the same data stream according to certain aspects of the present disclosure.

FIG. 1D shows an example in which multiple power amplifiers and multiple antennas are used to transmit a data stream and a phase-shifted version of the data stream according to certain aspects of the present disclosure.

FIG. 1E shows an example in which the output signals of two power amplifiers are combined according to certain aspects of the present disclosure.

FIG. 2A shows an example of a reconfigurable system including baluns and amplifiers in a first configuration according to certain aspects of the present disclosure.

FIG. 2B shows an example of the reconfigurable system of FIG. 2A in a second configuration according to certain aspects of the present disclosure.

FIG. 3 shows an example of an equivalent circuit of the reconfigurable system of FIG. 2A in the first configuration according to certain aspects of the present disclosure.

FIG. 4 shows an example of an equivalent circuit of the reconfigurable system of FIG. 2B in the second configuration according to certain aspects of the present disclosure.

FIG. 5 shows an example of the reconfigurable system of FIGS. 2A and 2B further including a reactive load according to certain aspects of the present disclosure.

FIG. 6A shows an example of a reconfigurable system including hybrid couplers and amplifiers in one configuration according to certain aspects of the present disclosure.

FIG. 6B shows an example of the reconfigurable system of FIG. 6A in another configuration according to certain aspects of the present disclosure.

FIG. 6C shows another example of a reconfigurable system including hybrid couplers and amplifiers in one configuration according to certain aspects of the present disclosure.

FIG. 6D shows an example of the reconfigurable system of FIG. 6C in another configuration according to certain aspects of the present disclosure.

FIG. 7A shows an example of an equivalent circuit of the reconfigurable system of FIG. 6A according to certain aspects of the present disclosure.

FIG. 7B shows an example of an equivalent circuit of the reconfigurable system of FIG. 6C according to certain aspects of the present disclosure.

FIG. 8 shows an example of an equivalent circuit of the reconfigurable system of FIG. 6B according to certain aspects of the present disclosure.

FIG. 9A shows an example of a reconfigurable system including input switching networks, hybrid couplers, and amplifiers in a first configuration according to certain aspects of the present disclosure.

FIG. 9B shows an example of the reconfigurable system of FIG. 9A in a second configuration according to certain aspects of the present disclosure.

FIG. 9C shows an example of the reconfigurable system of FIG. 9A in a third configuration according to certain aspects of the present disclosure.

FIG. 9D shows an example of the reconfigurable system of FIG. 9A in a fourth configuration according to certain aspects of the present disclosure.

FIG. 9E shows an exemplary implementation of transmit switches in a first configuration according to certain aspects of the present disclosure.

FIG. 9F shows an example of the transmit switches of FIG. 9E in a second configuration according to certain aspects of the present disclosure.

FIG. 10A shows an example of a reconfigurable system including a splitter, a phase shifter, and input switching networks in a first configuration according to certain aspects of the present disclosure.

FIG. 10B shows an example of the reconfigurable system of FIG. 10A in a second configuration according to certain aspects of the present disclosure.

FIG. 10C shows an example of the reconfigurable system of FIG. 10A in a third configuration according to certain aspects of the present disclosure.

FIG. 10D shows an example of the reconfigurable system of FIG. 10A in a fourth configuration according to certain aspects of the present disclosure.

FIG. 10E shows an example of the reconfigurable system of FIG. 10A in a fifth configuration according to certain aspects of the present disclosure.

FIG. 11 shows an example of a first mixer and a second mixer according to certain aspects of the present disclosure.

FIG. 12 is a diagram of an environment including an electronic device that includes a transceiver according to certain aspects of the present disclosure.

FIG. 13 is a flowchart illustrating an example of a method for wireless communications according to certain aspects of the present disclosure.

FIG. 14 is a flowchart illustrating another example of a method for wireless communications according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

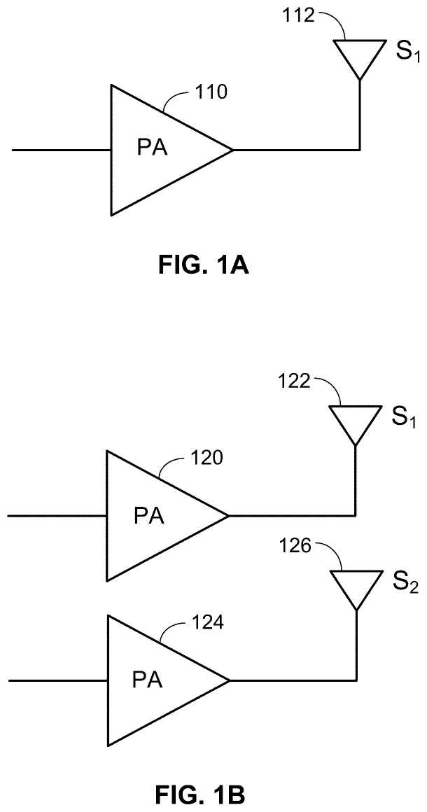

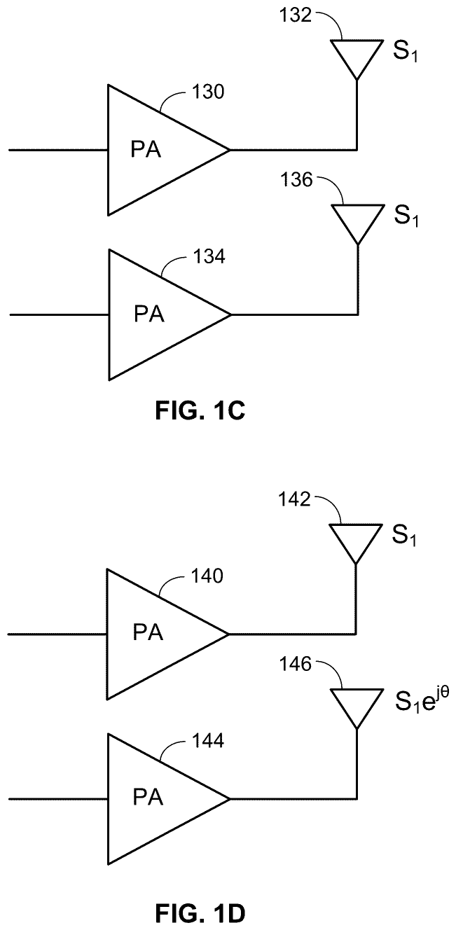

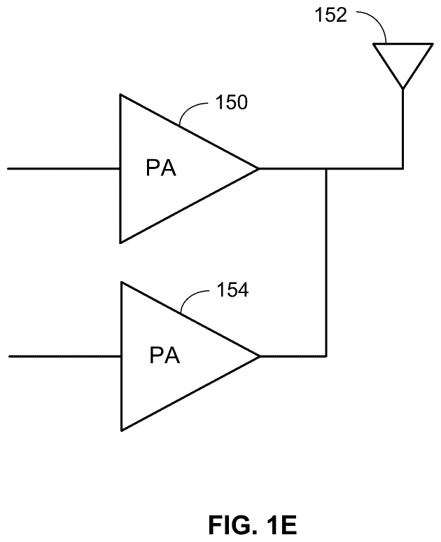

A wireless device (e.g., a mobile device) includes a transmitter for transmitting radio frequency (RF) signals via one or more antennas. The transmitter may include power amplifiers for amplifying the RF signals before transmission. It is desirable for the transmitter to support different power amplifier and antenna configurations for different uses cases. In this regard, FIGS. 1A to 1E illustrate examples of different power amplifier and antenna configurations for different uses according to certain aspects.

FIG. 1A shows an example in which a single power amplifier 110 and a single antenna 112 are used to transmit a single data stream S₁ (e.g., for high power user equipment (HPUE)). In this example, the power amplifier 110 amplifies an RF signal carrying the data stream S₁ and outputs the amplified RF signal to the antenna 112 for transmission.

FIG. 1B shows an example in which multiple power amplifiers 120 and 124 and multiple antennas 122 and 126 are used to transmit independent data streams S₁ and S₂ (e.g., for multiple-in-multiple-out (MIMO)). In this example, the power amplifier 120 amplifies a first RF signal carrying the data stream S₁ and outputs the amplified first RF signal to the antenna 122 for transmission. The power amplifier 124 amplifies a second RF signal carrying the data stream S₂ and outputs the amplified second RF signal to the antenna 126 for transmission.

FIG. 1C shows an example in which multiple power amplifiers 130 and 134 and multiple antennas 132 and 136 are used to transmit the same data stream S₁ (e.g., for transmit diversity (Tx)). In this example, the power amplifier 130 amplifies a first RF signal carrying the data stream S₁ and outputs the amplified first RF signal to the antenna 132 for transmission. The power amplifier 134 amplifies a second RF signal carrying the data stream S₁ and outputs the amplified second RF signal to the antenna 136 for transmission. In this example, the first RF signal and the second RF signal may be provided by splitting an RF signal carrying the data stream S₁ into the first RF signal and the second RF signal.

FIG. 1D shows an example in which multiple power amplifiers 140 and 144 and multiple antennas 142 and 146 are used to transmit a data stream S₁ and a phase-shifted version of the data stream S₁e^{jθ}(e.g., for beam forming). In this example, the power amplifier 140 amplifies a first RF signal carrying the data stream S₁ and outputs the amplified first RF signal to the antenna 142 for transmission. The power amplifier 144 amplifies a second RF signal carrying the phase-shifted version of the data stream S₁e^{jθ} and outputs the amplified second RF signal to the antenna 146 for transmission. In this example, the first RF signal and the second RF signal may be provided by splitting an RF signal carrying the data stream S₁ into the first RF signal and the second RF signal and shifting the phase of the second RF signal by the phase θ.

FIG. 1E shows an example in which the output signals of two power amplifiers 150 and 154 are combined to transmit on a single antenna 152 (e.g., to generate high power transmission for HPUE). In this example, the output of the power amplifier 150 and the output of the amplifier 154 are coupled to the antenna 152 to combine the output powers of the amplifiers 150 and 154.

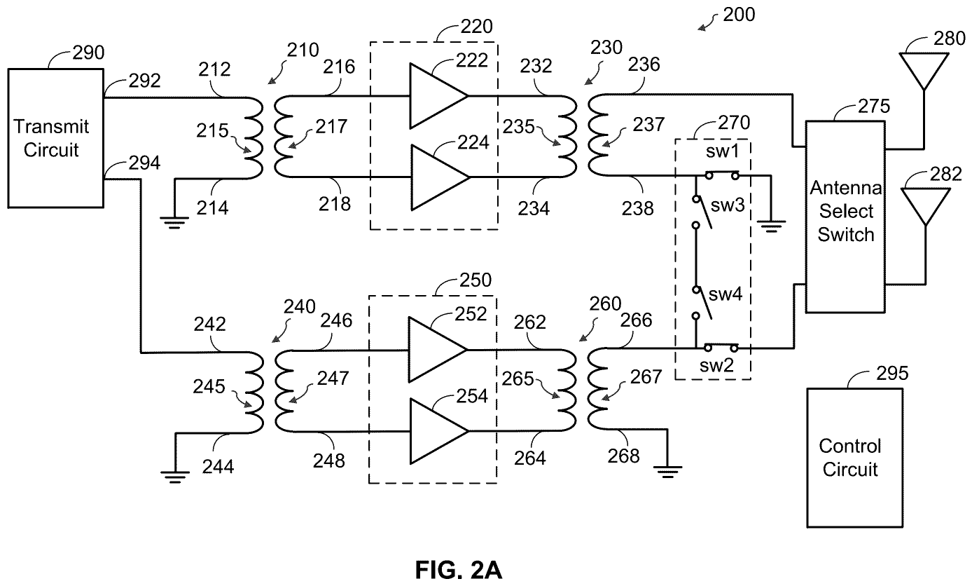

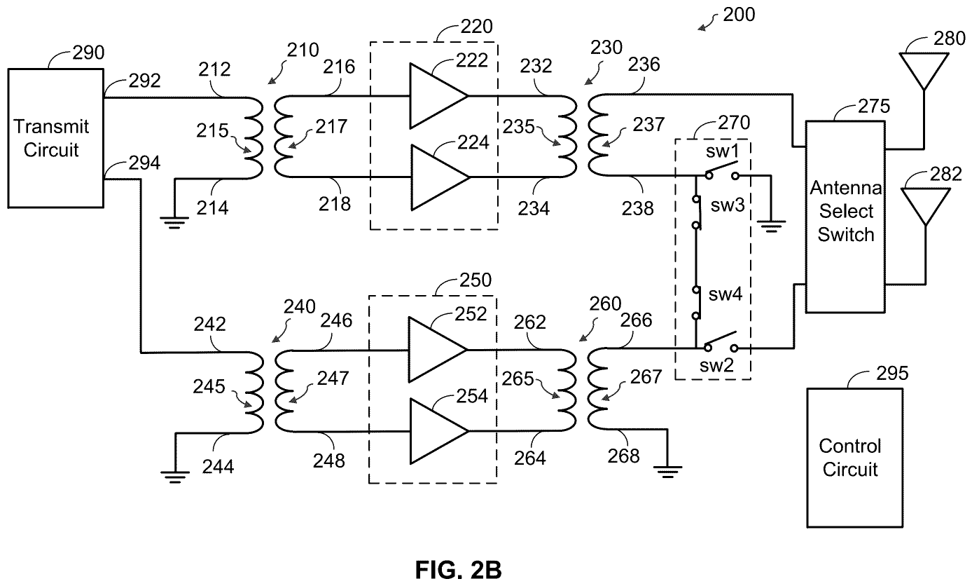

FIGS. 2A and 2B show an example of a system 200 that can be reconfigured to support wireless transmission for different uses cases (e.g., two or more of the exemplary use cases illustrated in FIGS. 1A to 1E). In this example, the system 200 includes a first antenna 280, a second antenna 282, a first amplifying circuit 220, a second amplifying circuit 250, a first input balun 210, a second input balun 240, a first output balun 230, a second output balun 260, a transmit circuit 290, a switching network 270, and an antenna select switch 275 (also referred to as an antenna switch module (ASM)). As used herein, a “switching network” is a network including two or more switches. Each of the two or more switches may be implemented with one or more respective transistors, a respective transmission gate, or another type of switch.

The first amplifying circuit 220 includes a first amplifier 222 and a second amplifier 224. Each of the amplifiers 222 and 224 may include one or more amplifier stages. The second amplifying circuit 250 includes a third amplifier 252 and a fourth amplifier 254. Each of the amplifiers 252 and 254 may include one or more amplifier stages. In certain aspects, the amplifiers 222, 224, 252, and 254 may be integrated on a chip (e.g., using a gallium arsenide (GaAs) process technology). For example, the amplifiers 222, 224, 252, and 254 may be integrated on the same die (e.g., GaAs die) or separate dies (e.g., GaAs dies). Each of the amplifiers 222, 224, 252, and 254 may include a transistor in a common-source amplifier configuration or a common-emitter amplifier configuration. The transistor may include a hetrojunction bipolar transistor (HBT), a bipolar junction transistor (BJT), a field effect transistor (FET), or another type of transistor. However, it is to be appreciated that the amplifiers 222, 224, 252, and 254 are not limited to these examples.

The first input balun 210 includes a primary inductor 215 and a secondary inductor 217 magnetically coupled with the primary inductor 215. Each of the inductors 215 and 217 may include a loop inductor, a spiral inductor, or another type of inductor. In this example, a first terminal 212 of the primary inductor 215 is coupled to a first output 292 of the transmit circuit 290 and a second terminal 214 of the primary inductor 215 is coupled to ground (or some reference potential). A first terminal 216 of the secondary inductor 217 is coupled to an input of the first amplifier 222 and a second terminal 218 of the secondary inductor 217 is coupled to an input of the second amplifier 224.

The second input balun 240 includes a primary inductor 245 and a secondary inductor 247 magnetically coupled with the primary inductor 245. Each of the inductors 245 and 247 may include a loop inductor, a spiral inductor, or another type of inductor. In this example, a first terminal 242 of the primary inductor 245 is coupled to a second output 294 of the transmit circuit 290 and a second terminal 244 of the primary inductor 245 is coupled to ground (or some reference potential). A first terminal 246 of the secondary inductor 247 is coupled to an input of the third amplifier 252 and a second terminal 248 of the secondary inductor 247 is coupled to an input of the fourth amplifier 254.

The first output balun 230 includes a primary inductor 235 and a secondary inductor 237 magnetically coupled with the primary inductor 235. Each of the inductors 235 and 237 may include a loop inductor, a spiral inductor, or another type of inductor. In this example, a first terminal 232 of the primary inductor 235 is coupled to an output of the first amplifier 222 and a second terminal 234 of the primary inductor 235 is coupled to an output of the second amplifier 224. A first terminal 236 of the secondary inductor 237 is coupled to the antenna select switch 275 and a second terminal 238 of the secondary inductor 237 is coupled to the switching network 270.

The second output balun 260 includes a primary inductor 265 and a secondary inductor 267 magnetically coupled with the primary inductor 265. Each of the inductors 265 and 267 may include a loop inductor, a spiral inductor, or another type of inductor. In this example, a first terminal 262 of the primary inductor 265 is coupled to an output of the third amplifier 252 and a second terminal 264 of the primary inductor 265 is coupled to an output of the fourth amplifier 254. A first terminal 266 of the secondary inductor 267 is coupled to the switching network 270 and a second terminal 268 of the secondary inductor 267 is coupled to ground (or some reference potential).

The switching network 270 includes a first switch sw1, a second switch sw2, a third switch sw3, and a fourth switch sw4. The first switch sw2 is coupled between the second terminal 238 of the secondary inductor 237 and ground (or some reference potential). The second switch sw2 is coupled between the first terminal 266 of the secondary inductor 267 and the antenna select switch 275. The third switch sw3 and the fourth switch sw4 are coupled in series between the second terminal 238 of the secondary inductor 237 and the first terminal 266 of the secondary inductor 267. The on/off states of the switches sw1, sw2, sw3, and sw4 are controlled by a control circuit 295. For ease of illustration, the individual connections between the control circuit 295 and the switches sw1, sw2, sw3, and sw4 are not shown in FIGS. 2A and 2B. As discussed further below, the switches sw1, sw2, sw3, and sw4 are used to switch the system 200 between a first configuration shown in FIG. 2A and a second configuration shown in FIG. 2B to support different uses cases.

The transmit circuit 290 is configured to output a first RF signal to the first input balun 210 via the first output 292 and output a second RF signal to the second input balun 240 via the second output 294. The transmit circuit 290 may be implemented with a software define radio (SDR) running on a processor, hardware (e.g., mixers, filters, power splitter, phase shifter, etc.), or a combination of both. The transmit circuit 290 may be configured to include the same data stream in the first and second RF signals, include different data streams in the first and second RF signals, and/or provide a phase shift between the first and second RF signals to support different use cases, as discussed further below.

FIG. 2A shows an example of the system 200 in the first configuration. In the first configuration, the control circuit 295 closes (i.e., turns on) the first switch sw1 and the second switch sw2 and opens (i.e., turns off) the third switch sw3 and the fourth switch sw4. As a result, the second terminal 238 of the secondary inductor 237 is coupled to ground, and the first terminal 266 of the secondary inductor 267 is coupled to the antenna select switch 275. The antenna select switch 275 may couple the first terminal 236 of the secondary inductor 237 to the first antenna 280 and couple the first terminal 266 of the secondary inductor 267 to the second antenna 282, or vice versa.

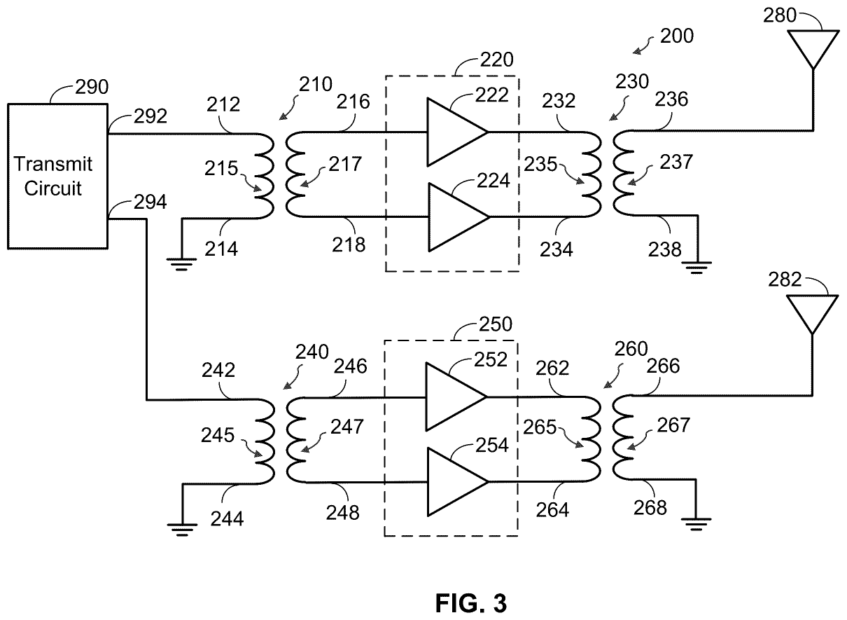

FIG. 3 shows an example of an equivalent circuit of the system 200 in the first configuration. In the example in FIG. 3, the antenna select switch 275 (shown in FIG. 2A) couples the first terminal 236 of the secondary inductor 237 to the first antenna 280 and couples the first terminal 266 of the secondary inductor 267 to the second antenna 282. However, it is to be appreciated that the antenna select switch 275 (shown in FIG. 2A) may couple the first terminal 236 of the secondary inductor 237 to the second antenna 282 and couple the first terminal 266 of the secondary inductor 267 to the first antenna 280 in another example.

In the first configuration, the first amplifying circuit 220 and the second amplifying circuit 250 may operate as independent differential amplifiers, in which the first amplifying circuit 220 amplifies the first RF signal for transmission via the first antenna 280 and the second amplifying circuit 250 amplifies the second RF signal for transmission via the second antenna 282, or vice versa.

In this example, the first input balun 210 couples the first RF signal from the transmit circuit 290 to the first amplifying circuit 220 as a differential signal. The first amplifying circuit 220 amplifies the first RF signal using the first amplifier 222 and the second amplifier 224. The first output balun 230 couples the resulting amplified first RF signal from the first amplifying circuit 220 to the first antenna 280 as a single-ended signal. In this example, a center tap (not shown) of the secondary inductor 217 and/or a center tap (not shown) of the primary inductor 235 may be coupled to a bias voltage.

The second input balun 240 couples the second RF signal from the transmit circuit 290 to the second amplifying circuit 250 as a differential signal. The second amplifying circuit 250 amplifies the second RF signal using the third amplifier 252 and the fourth amplifier 254. The second output balun 260 couples the resulting amplified second RF signal from the second amplifying circuit 250 to the second antenna 282 as a single-ended signal. In this example, a center tap (not shown) of the secondary inductor 247 and/or a center tap (not shown) of the primary inductor 265 may be coupled to a bias voltage.

In the first configuration, the transmit circuit 290 may include a first data stream in the first RF signal and a second data stream in the second RF signals to transmit the first data stream and the second data stream streams via the first antenna 280 and the second antenna 282, respectively (e.g., the use case illustrated in FIG. 1B). In another example, the transmit circuit 290 may include the same data stream in the first RF signal and the second RF signal to transmit the same data stream via the antennas 280 and 282 (e.g., the use case illustrated in FIG. 1C). In another example, the transmit circuit 290 may include the same data stream in the first RF signal and the second RF signal and shift the phase of the second RF signal by the phase θ (e.g., the use case illustrated in FIG. 1D). For a hardware implementation, the transmit circuit 290 may split an RF signal into the first RF signal and the second RF signal using a power splitter and shift the phase of the second RF signal using a phase shifter. In another example, the first amplifying circuit 220 may be used to amplify the first RF signal for transmission via the first antenna 280 with the second amplifying circuit 250 powered down (e.g., the use case illustrated in FIG. 1). It is to be appreciated that the first configuration is not limited to the exemplary use cases discussed above.

FIG. 2B shows an example of the system 200 in the second configuration. In the second configuration, the control circuit 295 opens (i.e., turns off) the first switch sw1 and the second switch sw2 and closes (i.e., turns on) the third switch sw3 and the fourth switch sw4. As a result, the first terminal 266 of the secondary inductor 267 is coupled to the second terminal 238 of the secondary inductor 237. The antenna select switch 275 may couple the first terminal 236 of the secondary inductor 237 to the first antenna 280 or the second antenna 282.

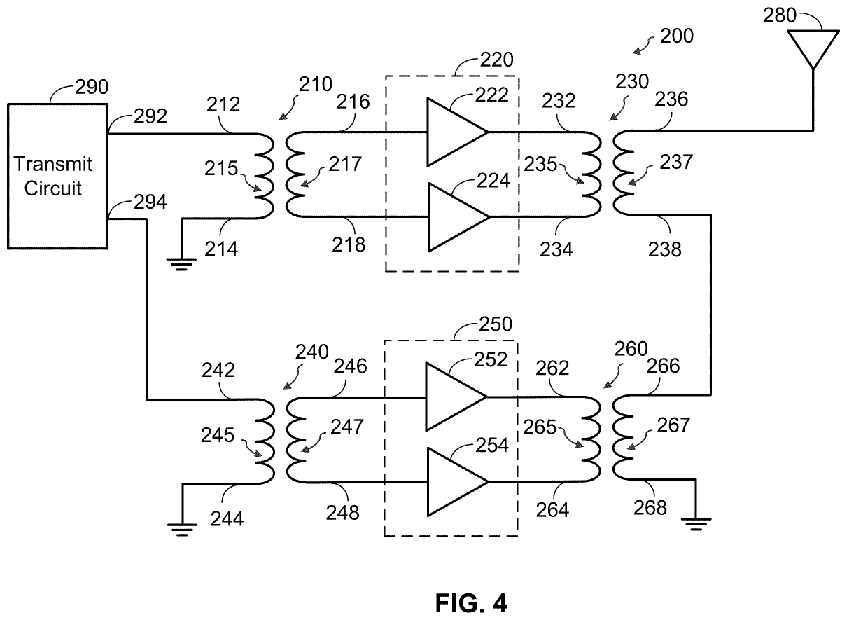

FIG. 4 shows an example of an equivalent circuit of the system 200 in the second configuration. In this configuration, the secondary inductor 237 and the secondary inductor 267 are coupled in series between the first antenna 280 and ground. This causes the baluns 230 and 260 to power combine the output signals of the amplifying circuits 220 and 250 through voltage-mode power combining. However, it is to be appreciated that the present disclosure is not limited to this example.

In the second configuration, the output signals of the first amplifying circuit 220 and the second amplifying circuit 250 are power combined and the resulting power combined signal is transmitted via the first antenna 820 or the second antenna 822 depending on which one of the antennas 820 and 822 is coupled to the first terminal 236 of the secondary inductor 237. In this example, the transmit circuit 290 may include the same data stream in the first RF signal and the second RF signal. The second configuration may be used, for example, to combine the powers of the amplifying circuits 220 and 250 for transmission on the first antenna 820 or the second antenna 882. Combining the powers of the amplifying circuits 220 and 250 provides higher transmission power compared with using only one of the amplifying circuits 220 and 250. For example, the power combining may double the transmission power (i.e., 3 dB increase) compared with using only one of the amplifying circuits 220 and 250. The power combining may be used, for example, for uses cases where a higher transmission power is desirable (e.g., to generate high power transmission for HPUE).

In the second configuration, the system 200 may be operated as a Doherty amplifier according to certain aspects. In this example, the first amplifying circuit 220 may be biased in class AB to operate as a differential main amplifier and the second amplifying circuit 250 may be biased in class C to operate as a differential auxiliary amplifier. Also, the second output balun 260 may be implemented with an impedance inverting balun. For example, one or more capacitors (not shown) may be coupled to the primary inductor 265 and/or the secondary inductor 267 to implement a lumped inductor-capacitor (LC) impedance inverter. The impedance inversion provides load modulation that allows the Doherty amplifier to achieve high power efficiency when the first amplifying circuit 220 (which operates as the main amplifier) is driven in the saturation region. The impedance inversion also introduces a phase shift. In this regard, the transmit circuit 290 may provide a phase shift (e.g., 90-degree phase shift) between the first RF signal and the second RF signal that compensates for the phase shift of the impedance inversion in order to provide in-phase power combining at the output baluns 230 and 260.

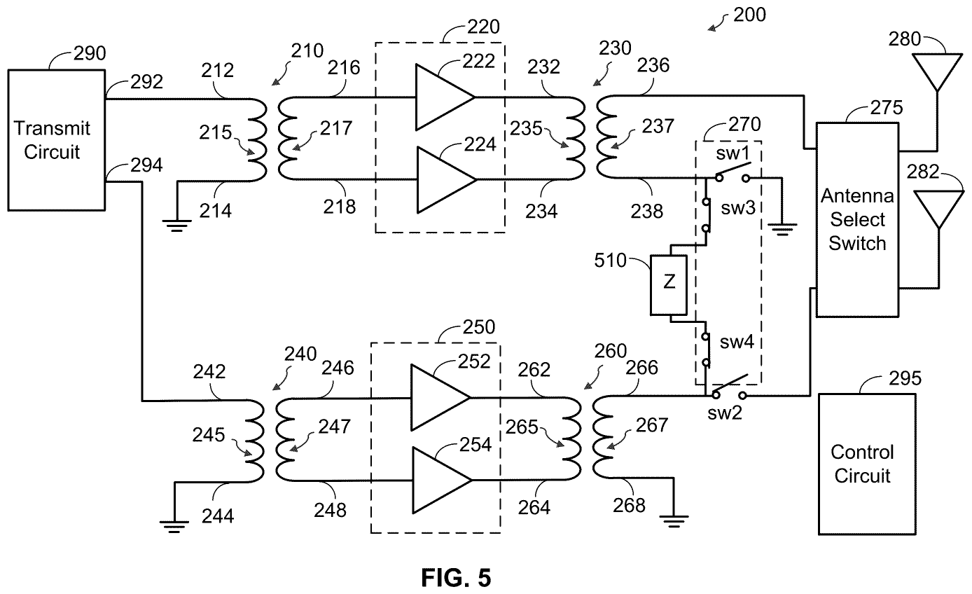

In the second configuration, the system 200 may also be operated in an outphasing mode. In this example, the outphasing mode may provide high power efficiency by having the transmit circuit 290 provide a phase shift between the first RF signal and the second RF signal, operating each of the amplifying circuits 220 and 250 at or near saturation, and power combining the output signals of the amplifying circuits 220 and 250 in phase using load modulation. In certain aspects, the system 200 may include a reactive load 510 coupled between the third switch sw3 and the fourth switch sw4 to provide load modulation for the outphasing mode, as shown in FIG. 5. The reactive load 510 may include one or more capacitors and/or one or more inductors. In this example, the reactance of the reactive load 510 may be chosen to achieve a load modulation that provides high power efficiency in the outphasing mode. The reactive load 510 may also be used to provide impedance inversion for Doherty operation.

It is to be appreciated that the switching network 270 is not limited to the exemplary implementation shown in FIGS. 2A and 2B. For example, in some implementations, the switching network 270 may include one switch coupled between the second terminal 238 of the secondary inductor 237 and the first terminal 266 of the secondary inductor 267. In general, the switching network 270 includes at least one switch coupled between the second terminal 238 of the secondary inductor 237 and the first terminal 266 of the secondary inductor 267, in which the at least one switch is open in the first configuration and closed in the second configuration. It is to also to be appreciated that the system 200 may include one or more additional circuits not shown in FIGS. 2A and 2B such as transmit filters. The antenna select switch 275 may be omitted for implementations where antenna switching is not used. In these implementations, the first terminal 236 of the secondary inductor 237 may be coupled to the first antenna 280 and the second switch sw2 may be coupled between the first terminal 266 of the secondary inductor 267 and the second antenna 282.

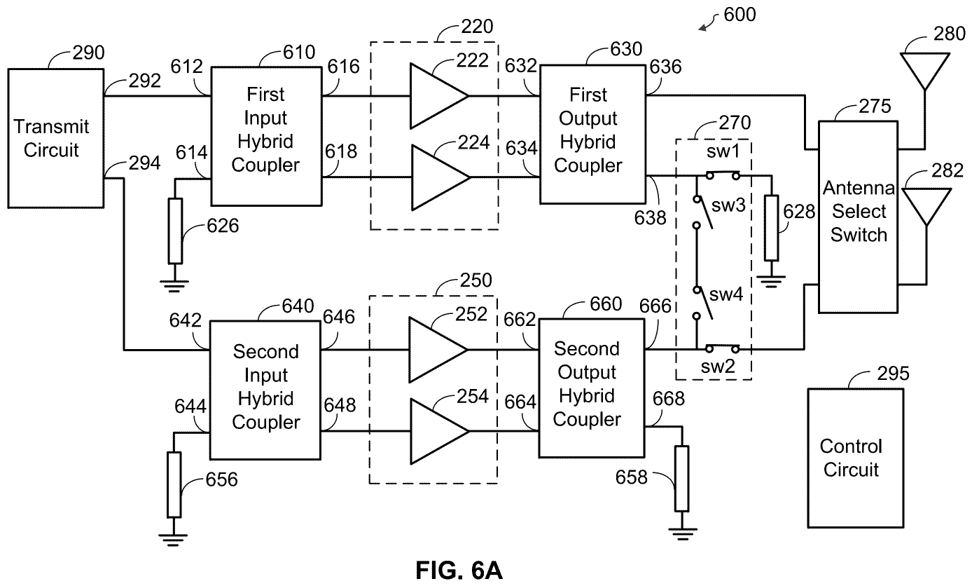

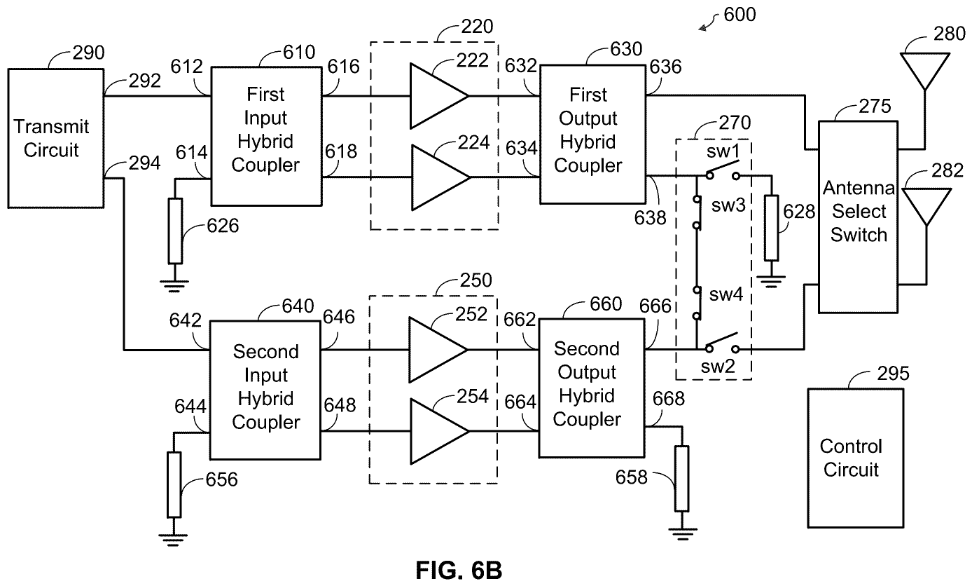

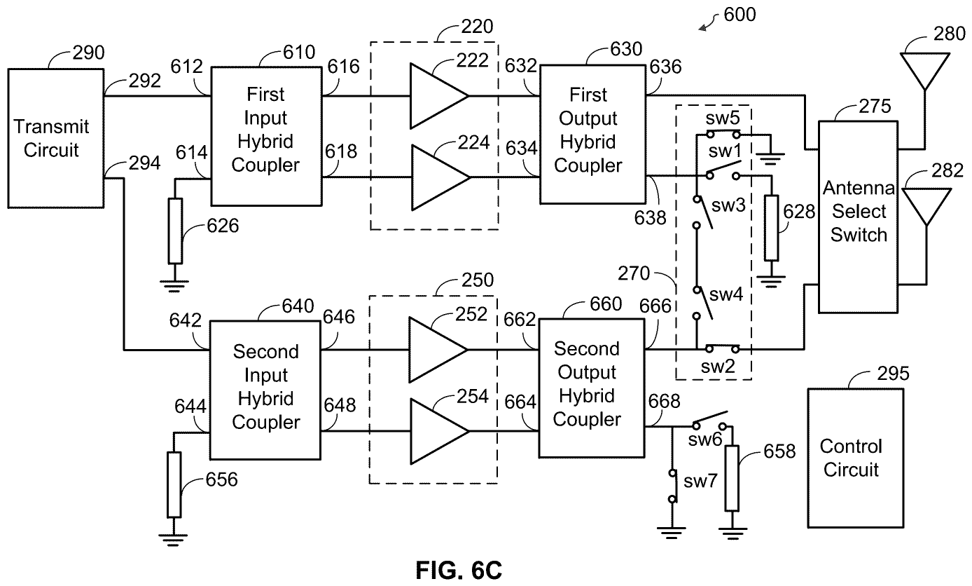

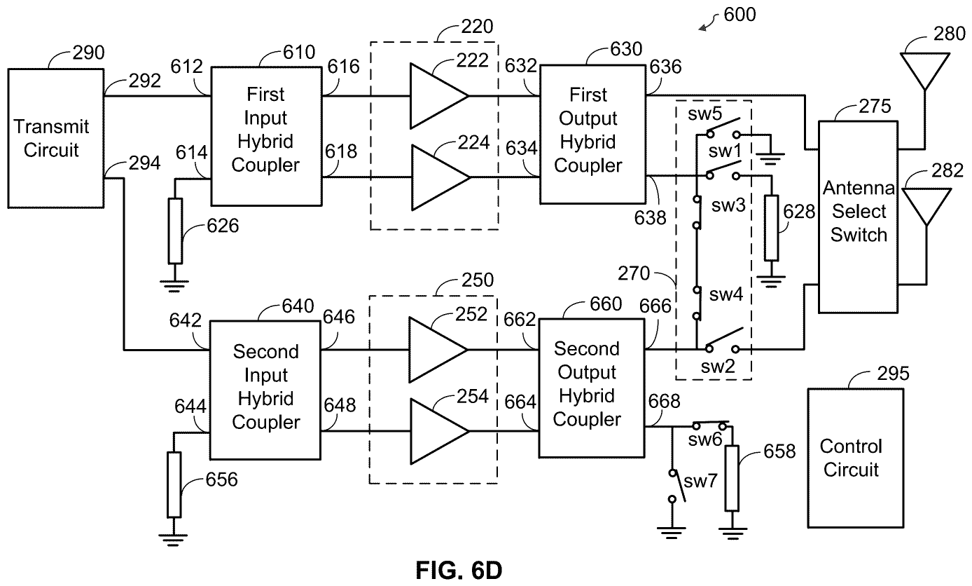

FIGS. 6A and 6B show an example of a system 600 that can be reconfigured to support wireless transmission for different uses cases (e.g., two or more of the exemplary use cases illustrated in FIGS. 1A to 1E). In this example, the system 600 includes the first antenna 280, the second antenna 282, the first amplifying circuit 220, the second amplifying circuit 250, the transmit circuit 290, the switching network 270, and the antenna select switch 275 discussed above. The system 600 also includes a first input hybrid coupler 610, a second input hybrid coupler 640, a first output hybrid coupler 630, and a second output hybrid coupler 660. Each of the hybrid couplers 610, 630, 640, and 660 may be implemented with a network of capacitors and inductors, a branch-line coupler, a hybrid ring coupler, or another type of circuit implementing a hybrid coupler.

The first input hybrid coupler 610 has a first port 612, a second port 614, a third port 616, and a fourth port 618. In this example, the first port 612 is coupled to the first output 292 of the transmit circuit 290, the second port 614 is coupled to a termination load 626, the third port 616 is coupled to the input of the first amplifier 222, and the fourth port 618 is coupled to the input of the second amplifier 224.

The second input hybrid coupler 640 has a first port 642, a second port 644, a third port 646, and a fourth port 648. In this example, the first port 642 is coupled to the second output 294 of the transmit circuit 290, the second port 644 is coupled to a termination load 656, the third port 646 is coupled to the input of the third amplifier 252, and the fourth port 648 is coupled to the input of the fourth amplifier 254.

The first output hybrid coupler 630 has a first port 632, a second port 634, a third port 636, and a fourth port 638. In this example, the first port 632 is coupled to the output of the first amplifier 222, the second port 634 is coupled to the output of the second amplifier 224, and the third port 636 is coupled to the antenna select switch 275. The first switch sw1 is coupled between the fourth port 638 and a termination load 628.

The second output hybrid coupler 660 has a first port 662, a second port 664, a third port 666, and a fourth port 668. In this example, the first port 662 is coupled to the output of the third amplifier 252, the second port 664 is coupled to the output of the fourth amplifier 254, and the fourth port 668 is coupled to a termination load 658. The second switch sw2 is coupled between the third port 666 and the antenna select switch 275. The third switch sw3 and the fourth switch sw4 are coupled in series between the fourth port 638 of the first output hybrid coupler 630 and the third port 666 of the second output hybrid coupler 660.

Each of the termination loads 626, 628, 644, and 658 may be implemented with a matched load (e.g., 50 Ohms). In some implementations, the termination loads 626, 628, 644, and/or 658 may be omitted with the respective port or switch coupled to ground or open, as discussed further below.

FIG. 6A shows an example of the system 600 in a first configuration. In the first configuration, the control circuit 295 closes (i.e., turns on) the first switch sw1 and the second switch sw2 and opens (i.e., turns off) the third switch sw3 and the fourth switch sw4. As a result, the fourth port 638 of the first output hybrid coupler 630 is coupled to the termination load 628. The antenna select switch 275 may couple the third port 636 of the first output hybrid coupler 630 to the first antenna 280 and couple the third port 666 of the second output hybrid coupler 660 to the second antenna 282, or vice versa.

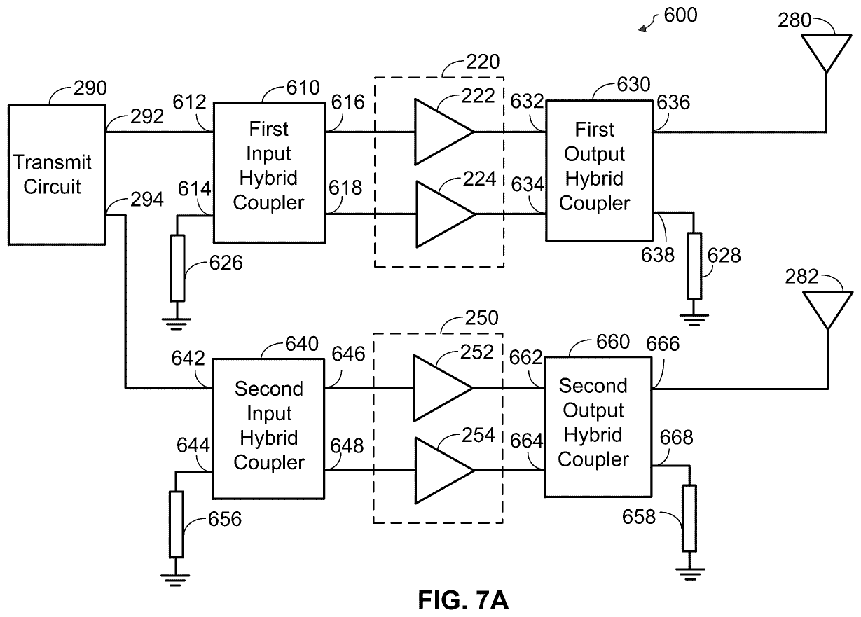

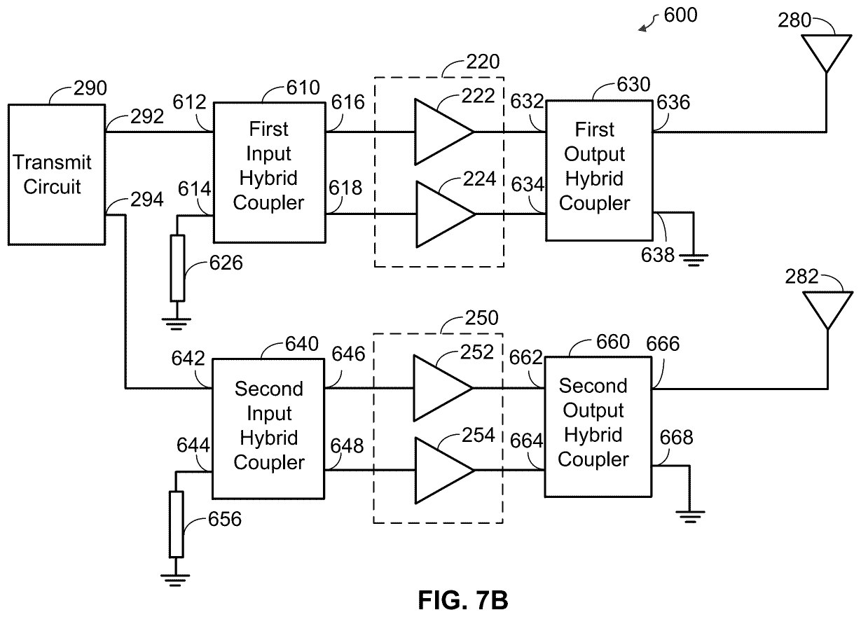

FIG. 7A shows an example of an equivalent circuit of the system 600 in the first configuration. In the example in FIG. 7A, the antenna select switch 275 (shown in FIG. 6A) couples the third port 636 of the first output hybrid coupler 630 to the first antenna 280 and couples the third port 666 of the second output hybrid coupler 660 to the second antenna 282. However, it is to be appreciated that the antenna select switch 275 (shown in FIG. 2A) may couple the third port 636 of the first output hybrid coupler 630 to the second antenna 282 and couple to the third port 666 of the second output hybrid coupler 660 to the first antenna 280 in another example.

In the first configuration, the first amplifying circuit 220 and the second amplifying circuit 250 may operate as independent balanced amplifiers, in which the first amplifying circuit 220 amplifies the first RF signal for transmission via the first antenna 280 and the second amplifying circuit 250 amplifies the second RF signal for transmission via the second antenna 282, or vice versa.

In this example, the first input hybrid coupler 610 may split the first RF signal into two RF signals that are 90 degrees out of phase, output one of the two RF signals to the input of the first amplifier 222 via the third port 616, and output the other one of the two RF signals to the input of the second amplifier 224 via the fourth port 618. The first output hybrid coupler 630 may then combine the output signals of the amplifiers 222 and 224 in phase and output the resulting combined output signal at the third port 636 for transmission via the first antenna 280.

In this example, the second input hybrid coupler 640 may split the second RF signal into two RF signals that are 90 degrees out of phase, output one of the two RF signals to the input of the third amplifier 252 via the third port 646, and output the other one of the two RF signals to the input of the fourth amplifier 254 via the fourth port 648. The second output hybrid coupler 660 may then combine the output signals of the amplifiers 252 and 254 in phase and output the resulting combined output signal at the third port 666 for transmission via the second antenna 282.

In the first configuration, the transmit circuit 290 may include a first data stream in the first RF signal and a second data stream in the second RF signals to transmit the first data stream and the second data stream streams via the first antenna 280 and the second antenna 282, respectively (e.g., the use case illustrated in FIG. 1B). In another example, the transmit circuit 290 may include the same data stream in the first RF signal and the second RF signal to transmit the same data stream via the antennas 280 and 282 (e.g., the use case illustrated in FIG. 1C). In another example, the transmit circuit 290 may include the same data stream in the first RF signal and the second RF signal and shift the phase of the second RF signal by the phase θ (e.g., the use case illustrated in FIG. 1D). In another example, the first amplifying circuit 220 may be used to amplify the first RF signal for transmission via the first antenna 280 with the second amplifying circuit 250 powered down (e.g., the use case illustrated in FIG. 1). It is to be appreciated that the first configuration is not limited to the exemplary use cases discussed above.

The first amplifying circuit 220 and the second amplifying circuit 250 are not limited to operating as independent balanced amplifiers. For example, in other implementations, the first amplifying circuit 220 and the second amplifying circuit 250 may operate as independent Doherty amplifiers, as discussed further below.

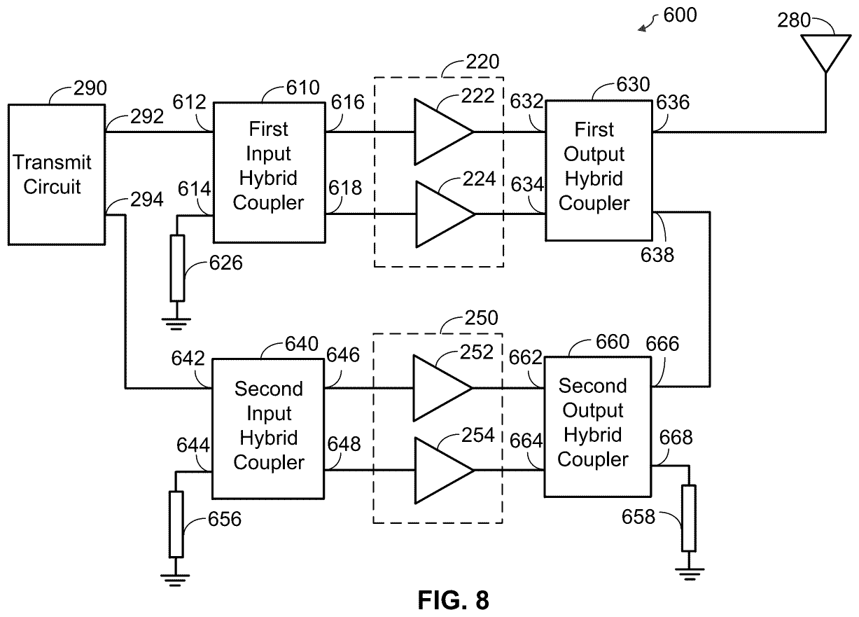

FIG. 6B shows an example of the system 600 in a second configuration for the exemplary implementation shown in FIG. 6A. In the second configuration, the control circuit 295 opens (i.e., turns off) the first switch sw1 and the second switch sw2 and closes (i.e., turns on) the third switch sw3 and the fourth switch sw4. In this configuration, the third port 666 of the second output hybrid coupler 660 is coupled to the fourth port 638 of the first output hybrid coupler 630. The antenna select switch 275 may couple the third port 636 of the first output hybrid coupler 630 to the first antenna 280 or the second antenna 282. FIG. 8 shows an example of an equivalent circuit of the system 600 in the second configuration.

In the second configuration, the system 600 may operate as a load modulation balanced amplifier (LMBA) in which the output signal of the second output hybrid coupler 660 (which is the combined output signal of the amplifiers 252 and 254) is injected into the fourth port 638 of the first output hybrid coupler 630. The first output hybrid coupler 630 power combines the output signal of the second output hybrid coupler 660 with the combined output signal of the amplifiers 222 and 224 and outputs the resulting powered combined signal at the third port 636 for transmission.

The signal injection into the fourth port 638 of the first output hybrid coupler 630 modulates the load seen at the outputs of the amplifiers 222 and 224. In this example, the transmit circuit 290 may shift the phase between the first RF signal and the second RF signal such that the load modulation constructively combines the combined output signal of the amplifiers 222 and 224 and the combined output signal of the amplifiers 252 and 254. The phase shift may be selected, for example, by plotting the power efficiency of the system 600 as a function of phase shift, and selecting a phase shift that provides high power efficiency. In this example, the second RF signal may be a phase-shifted version of the first RF signal.

In some implementations, the first amplifying circuit 220 and the second amplifying circuit 250 may operate as independent Doherty amplifiers by coupling the fourth port 638 of the first output hybrid coupler 630 to ground or open and coupling the fourth port 668 of the second output hybrid coupler 660 to ground or open.

In this regard, FIGS. 6C and 6D show an example in which the system 600 further includes a fifth switch sw5, a sixth switch sw6, and a seventh switch sw7 to support additional configurations. The fifth switch sw5 may be included in the switching network 270. In this example, the fifth switch sw5 is coupled between the fourth port 638 of the first output hybrid coupler 630 and ground, the sixth switch sw6 is coupled between the fourth port 668 of the second output hybrid coupler 660 and the termination load 658, and the seventh switch sw7 is coupled between the fourth port 668 of the second output hybrid coupler 660 and ground. The on/off states of the switches sw5, sw6, and sw7 may be controlled by the control circuit 295.

In this example, the first switch sw1 and the fifth switch sw5 allow the control circuit 295 to selectively couple the fourth port 638 of the first output hybrid coupler 630 to the termination load 628 or ground when the third and fourth switches sw3 and sw4 are open. For example, when the first amplifying circuit 220 is used as an independent balanced amplifier, the control circuit 295 may close the first switch sw1 and open the fifth switch sw5 to couple the fourth port 638 of the first output hybrid coupler 630 to the termination load 628. When the first amplifying circuit 220 is used as an independent Doherty amplifier, the control circuit 295 may couple the fourth port 638 of the first output hybrid coupler 630 to ground or open (e.g., depending on whether the phase at the fourth port 618 of the first input hybrid coupler 610 leads or lags the phase at the third port 616 of the first input hybrid coupler 610 by 90 degrees). To couple the fourth port 638 to ground, the control circuit 295 may open the first switch sw1 and close the fifth switch sw5 to couple the fourth port 638 of the first output hybrid coupler 630 to ground. To open the fourth port 638, the control circuit 295 may open both switches sw1 and sw5. In this example, the amplifier 222 may be biased in class AB to operate as a main amplifier and the amplifier 224 may be biased in class C to operate as an auxiliary amplifier, or vice versa.

In this example, the sixth switch sw6 and the seventh switch sw7 allow the control circuit 295 to selectively couple the fourth port 668 of the second output hybrid coupler 660 to the termination load 658 or ground when the third and fourth switches sw3 and sw4 are open. For example, when the second amplifying circuit 250 is used as an independent balanced amplifier, the control circuit 295 may close the sixth switch sw6 and open the seventh switch sw7 to couple the fourth port 668 of the second output hybrid coupler 660 to the termination load 658. When the second amplifying circuit 250 is used as an independent Doherty amplifier, the control circuit 295 may couple the fourth port 668 of the second output hybrid coupler 660 to ground or open (e.g., depending on whether the phase at the fourth port 648 of the second input hybrid coupler 640 leads or lags the phase at the third port 646 of the second input hybrid coupler 640 by 90 degrees). To couple the fourth port 668 to ground, the control circuit 295 may open the switch sw6 and close the seventh switch sw7 to couple the fourth port 668 of the second output hybrid coupler 660 to ground. To open the fourth port 668, the control circuit 295 may open both switches sw6 and sw7. In this example, the amplifier 252 may be biased in class AB to operate as a main amplifier and the amplifier 254 may be biased in class C to operate as an auxiliary amplifier, or vice versa.

FIG. 6C shows an example of the system 600 in a third configuration in which the control circuit 295 opens the switches s1, sw3, sw4, and sw6, and closes the switches sw2, sw5, and sw7. This configuration may be used, for example, to operate the first amplifying circuit 220 and the second amplifying circuit 250 as independent Doherty amplifiers, as discussed above. FIG. 7B shows an example of an equivalent circuit of the system 600 in the third configuration. In the example in FIG. 7B, the antenna select switch 275 (shown in FIG. 6C) couples the third port 636 of the first output hybrid coupler 630 to the first antenna 280 and couples the third port 666 of the second output hybrid coupler 660 to the second antenna 282. However, it is to be appreciated that the present disclosure is not limited to this example. In the example shown in FIG. 7B, the fourth port 638 of the first output hybrid coupler 630 is coupled to ground and the fourth port 668 of the second output hybrid coupler 660 is coupled to ground.

In another example, the control circuit 295 may open the switches s1, sw3, sw4, sw5, sw6, and sw7 and close the second switch sw2 in a fourth configuration (not shown). In this configuration, the fourth port 638 of the first output hybrid coupler 630 is open and the fourth port 668 of the second output hybrid coupler 660 is open.

In the third configuration or the fourth configuration, the transmit circuit 290 may include a first data stream in the first RF signal and a second data stream in the second RF signals to transmit the first data stream and the second data stream streams via the first antenna 280 and the second antenna 282, respectively (e.g., the use case illustrated in FIG. 1B). In another example, the transmit circuit 290 may include the same data stream in the first RF signal and the second RF signal to transmit the same data stream via the antennas 280 and 282 (e.g., the use case illustrated in FIG. 1C). In another example, the transmit circuit 290 may include the same data stream in the first RF signal and the second RF signal and shift the phase of the second RF signal by the phase θ (e.g., the use case illustrated in FIG. 1D). In another example, the first amplifying circuit 220 may be used to amplify the first RF signal for transmission via the first antenna 280 with the second amplifying circuit 250 powered down (e.g., the use case illustrated in FIG. 1). It is to be appreciated that the third configuration and the fourth configuration are not limited to the exemplary use cases discussed above.

FIG. 6D shows an example of the system 600 in a fifth configuration for the exemplary implementation shown in FIG. 6C. In this configuration, the control circuit 295 opens (i.e., turns off) the first switch sw1 and the second switch sw2 and closes (i.e., turns on) the third switch sw3 and the fourth switch sw4. The control circuit 295 also opens the switches sw5 and sw7 and closes the sixth switch sw6. In this configuration, the third port 666 of the second output hybrid coupler 660 is coupled to the fourth port 638 of the first output hybrid coupler 630. The antenna select switch 275 may couple the third port 636 of the first output hybrid coupler 630 to the first antenna 280 or the second antenna 282. In this example, the equivalent circuit of the system 600 in the fifth configuration may be the same as the equivalent circuit of the system 600 shown in FIG. 8 for the second configuration in which the third port 666 of the second output hybrid coupler 660 is coupled to the fourth port 638 of the first output hybrid coupler 630. In the fifth configuration, the system 600 may operate as a LMBA in the manner discussed above for the second configuration.

It is to be appreciated that the switching network 270 is not limited to the exemplary implementations shown in FIGS. 6A to 6D. For example, in some implementations, the switching network 270 may include one switch coupled between the fourth port 638 of the first output hybrid coupler 630 and the third port 666 of the second output hybrid coupler 660. In general, the switching network 270 includes at least one switch coupled between the fourth port 638 of the first output hybrid coupler 630 and the third port 666 of the second output hybrid coupler 660, in which the at least one switch is open in the first configuration, the third configuration, and the fourth configuration and the at least one switch is closed in the second configuration and the fifth configuration. It is to also to be appreciated that the system 200 may include one or more additional circuits not shown in FIGS. 6A to 6D such as transmit filters. The antenna select switch 275 may be omitted for implementations where antenna switching is not used. In these implementations, the third port 636 of the first output hybrid coupler 630 may be coupled to the first antenna 280 and the second switch sw2 may be coupled between the third port 666 of the second output hybrid coupler 660 and the second antenna 282. It is also to be appreciated that one or more of the exemplary switches discussed above may be omitted, for example, for implementations where one or more of the exemplary configurations discussed above are not used.

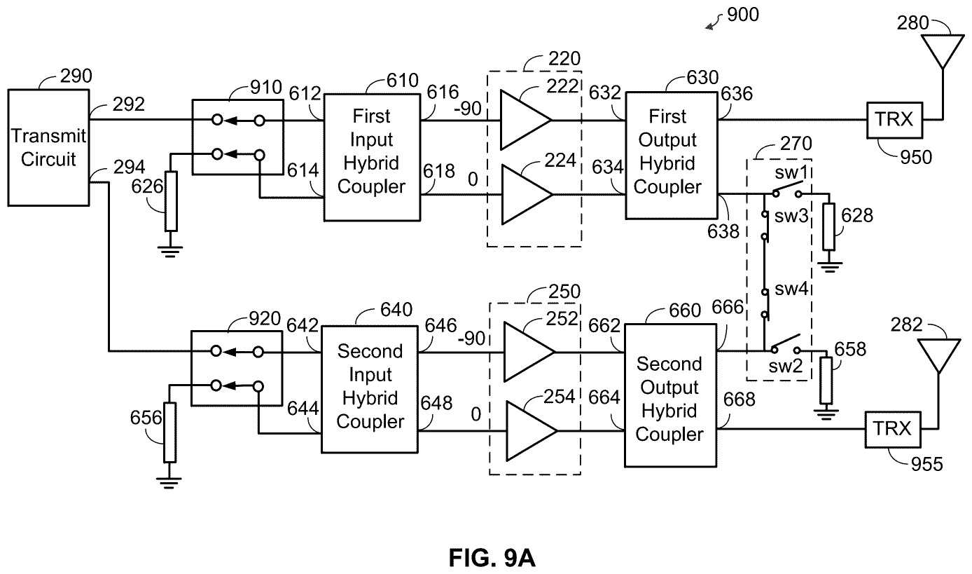

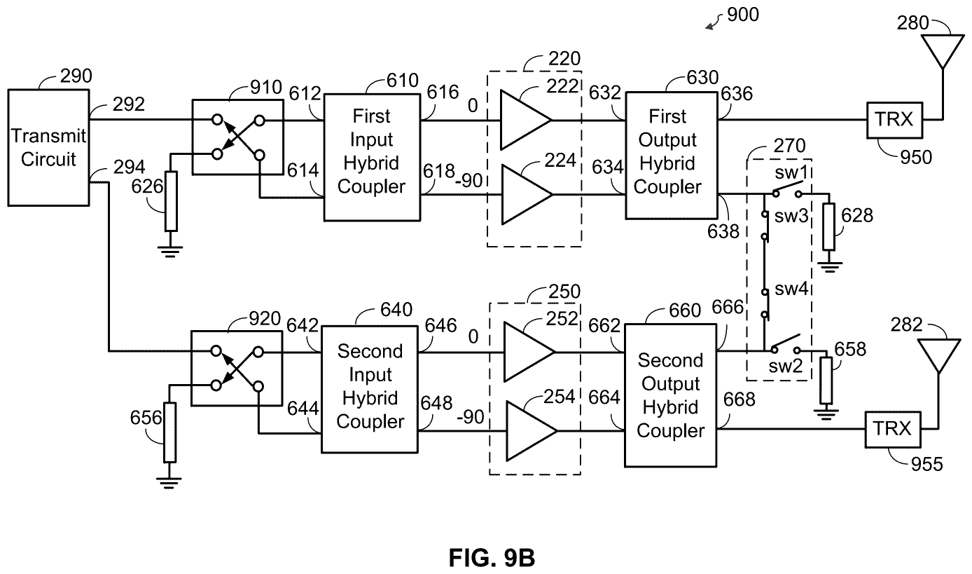

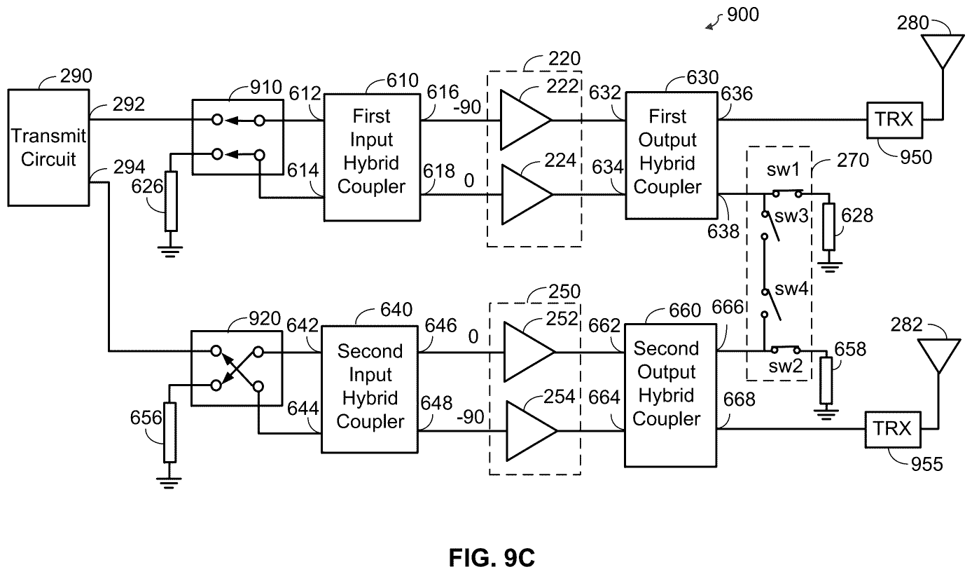

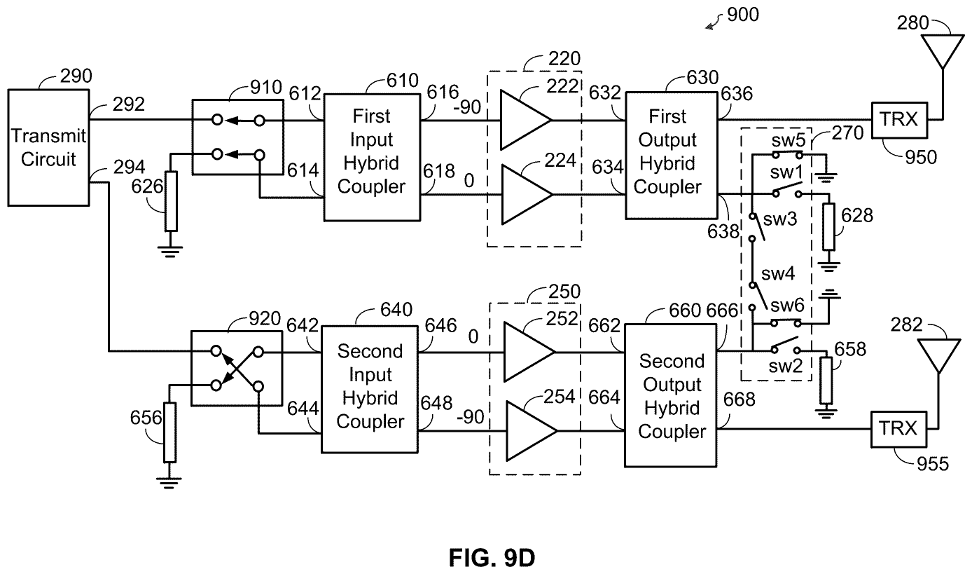

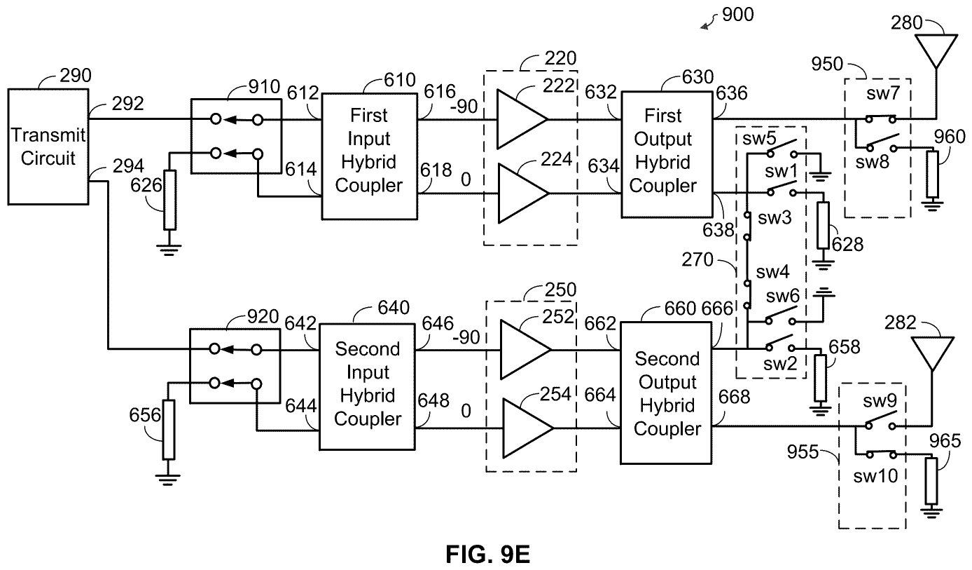

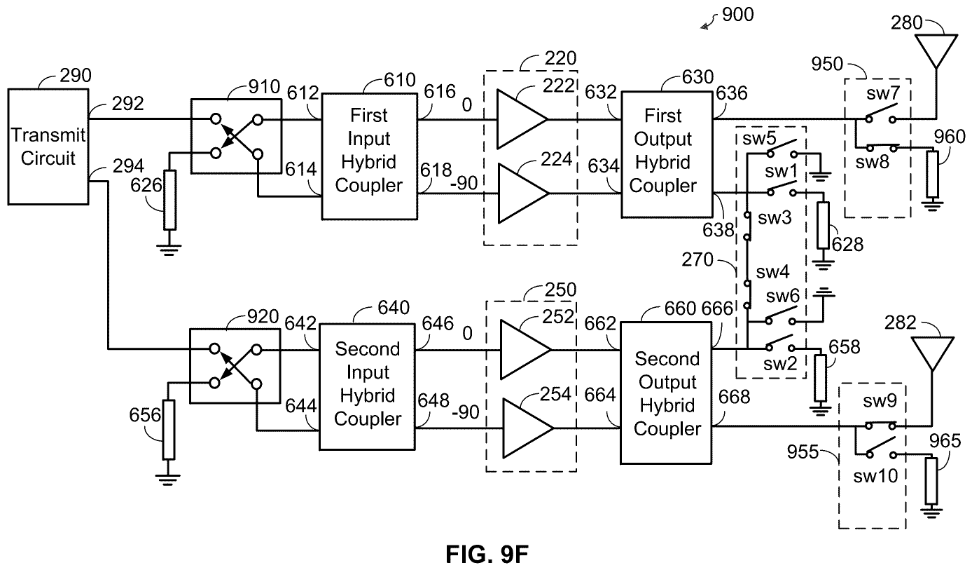

FIGS. 9A to 9F show an exemplary system 900 in which antenna switching is performed on the input side of the system 900 instead of using the antenna select switch 275 on the output side. In the example shown in FIGS. 9A to 9F, the third port 636 of first output hybrid coupler 630 is coupled to the first antenna 280 and the fourth port 668 of the second output hybrid coupler 660 is coupled to the second antenna 282. In some implementations, the system 900 may also include a first transmit switch 950 for selectively coupling the third port 636 of the first output hybrid coupler 630 to the first antenna 280, and a second transmit switch 955 for selectively coupling the fourth port 668 of the second output hybrid coupler 660 to the second antenna 282. However, it is to be appreciated that the present disclosure is not limited to this example. In this example, the system 900 may also include the switching network 270 in which the first switch sw1 is coupled between the fourth port 638 of the first output hybrid coupler 630 and the termination load 628, the second switch sw2 is coupled between the third port 666 of the second output hybrid coupler 660 and the termination load 658, and the third switch sw3 and the fourth switch sw4 are coupled in series between the fourth port 638 of the first output hybrid coupler 630 and the third port 666 of the second output hybrid coupler 660.

In this example, the system 900 includes a first input switching network 910 and a second input switching network 920. The first input switching network 910 is coupled to the first output 292 of the transmit circuit 290, the termination load 626, the first port 612 of the first input hybrid coupler 610, and the second port 614 of the first input hybrid coupler 610. The first input switching network 910 is configured to selectively couple the first output 292 of the transmit circuit 290 to the first port 612 or the second port 614 of the first input hybrid coupler 610 and selectively couple the termination load 626 to the first port 612 or the second port 614 of the first input hybrid coupler 610. The first input switching network 910 may be controlled by the control circuit 295 (shown in FIGS. 6A to 6D). The first input switching network 910 may be implemented with a network of two or more switches configured to perform switching functions of the first input switching network 910 described herein according to various aspects.

The second input switching network 920 is coupled to the second output 294 of the transmit circuit 290, the termination load 656, the first port 642 of the second input hybrid coupler 640, and the second port 644 of the second input hybrid coupler 640. The second input switching network 920 is configured to selectively couple the second output 294 of the transmit circuit 290 to the first port 642 or the second port 644 of the second input hybrid coupler 640 and selectively couple the termination load 656 to the first port 642 or the second port 644 of the second input hybrid coupler 640. The second input switching network 920 may be controlled by the control circuit 295 (shown in FIGS. 6A to 6D). The second input switching network 920 may be implemented with a network of two or more switches configured to perform switching functions of the second input switching network 920 described herein according to various aspects.

For power combining, the input switching networks 910 and 920 may be used to steer the power combined output signal of the amplifying circuits 220 and 250 to the first antenna 280 or the second antenna 282. In this regard, FIG. 9A shows an example of a first input switch configuration of the input switching networks 910 and 920 in which the power combined output signal is steered to the first antenna 280. In the first input switch configuration, the control circuit 295 causes the first input switching network 910 to couple the first output 292 of the transmit circuit 290 to the first port 612 of the first input hybrid coupler 610 and couple the termination load 626 to the second port 614 of the first input hybrid coupler 610. As a result, the transmit circuit 290 drives the first port 612 of the first input hybrid coupler 610 with the first RF signal.

Also, in the first input switch configuration, the control circuit 295 causes the second input switching network 920 to couple the second output 294 of the transmit circuit 290 to the first port 642 of the second input hybrid coupler 640 and couple the termination load 656 to the second port 644 of the second input hybrid coupler 640. As a result, the transmit circuit 290 drives the first port 642 of the second input hybrid coupler 640 with the second RF signal.

In the example in FIG. 9A, the third port 666 of the second output hybrid coupler 660 is coupled to the fourth port 638 of the first output hybrid coupler 630 (e.g., by having the control circuit 295 close the third switch sw3 and the fourth switch sw4 and open the first switch sw1 and the second switch sw2).

The first input switch configuration shown in FIG. 9A causes the second output hybrid coupler 660 to output the combined output signal of the amplifiers 252 and 254 at the third port 666 of the second output hybrid coupler 660. As a result, the combined output signal is injected into the fourth port 638 of the first output hybrid coupler 630. The first output hybrid coupler 630 power combines the combined output signal of the amplifiers 252 and 254 with the combined output signal of the amplifiers 222 and 224 and outputs the resulting power combined signal at the third port 636 of the first output hybrid coupler 630 for transmission via the first antenna 280. In this configuration, the fourth port 668 of the second output hybrid coupler 660 may be coupled to a termination load (e.g., 50 Ohm load), shorted to ground, or open, as discussed further below.

FIG. 9B shows an example of a second input switch configuration of the input switching networks 910 and 920 in which the power combined output signal is steered to the second antenna 282. In the second input switch configuration, the control circuit 295 causes the first input switching network 910 to couple the first output 292 of the transmit circuit 290 to the second port 614 of the first input hybrid coupler 610 and couple the termination load 626 to the first port 612 of the first input hybrid coupler 610. As a result, the transmit circuit 290 drives the second port 614 of the first input hybrid coupler 610 with the first RF signal.

Also, in the second input switch configuration, the control circuit 295 causes the second input switching network 920 to couple the second output 294 of the transmit circuit 290 to the second port 644 of the second input hybrid coupler 640 and couple the termination load 656 to the first port 642 of the second input hybrid coupler 640. As a result, the transmit circuit 290 drives the second port 644 of the second input hybrid coupler 640 with the second RF signal.

In the example in FIG. 9B, the third port 666 of the second output hybrid coupler 660 is coupled to the fourth port 638 of the first output hybrid coupler 630 (e.g., by having the control circuit 295 close the third switch sw3 and the fourth switch sw4 and open the first switch sw1 and the second switch sw2).

Thus, in the second input switch configuration, the transmit circuit 290 drives the second ports 614 and 644 of the input hybrid couplers 610 and 640 instead of the first ports 612 and 642 of the input hybrid couplers 610 and 640. This causes the first input hybrid coupler 610 to flip the 90-degree phase shift between the signals at the third port 616 and the fourth port 618 of the first input hybrid coupler 610 compared with the first input switch configuration in FIG. 9A. In this regard, FIGS. 9A and 9B show an example of the relative phases of the signals at the third port 616 and the fourth port 618 of the first input hybrid coupler 610 in which the 90-degree phase shift in FIG. 9B is flipped with respect to the 90-degree phase shift shown in FIG. 9A. In addition, the second input hybrid coupler 640 flips the 90-degree phase shift between the signals at the third port 646 and the fourth port 648 of the second input hybrid coupler 640 compared with the first input switch configuration shown in FIG. 9A.

The flipping of the 90-degree phase shift at the third port 616 and the fourth port 618 of the first input hybrid coupler 610 causes the first output hybrid coupler 630 to output the combined output signal of the amplifiers 222 and 224 at the fourth port 638 of the first output hybrid coupler 630. As a result, the combined output signal is injected into the third port 666 of the second output hybrid coupler 660. The second output hybrid coupler 660 power combines the combined output signal of the amplifiers 252 and 254 with the combined output signal of the amplifiers 222 and 224 and outputs the resulting power combined signal at the fourth port 668 of the second output hybrid coupler 660 for transmission via the second antenna 282. In this example, the flipping of the 90-degree phase shift at the third port 646 and the fourth port 648 of the second input hybrid coupler 610 causes the second output hybrid coupler 660 to output the power combined signal at the fourth port 668. In this configuration, the third port 636 of the first output hybrid coupler 630 may be coupled to a termination load (e.g., 50 Ohm load), shorted to ground, or open, as discussed further below.

FIG. 9C shows an example of a third input switch configuration of the input switching networks 910 and 920 in which the combined output signal of the amplifiers 222 and 224 of the first amplifying circuit 220 is steered to the first antenna 280 and the combined output signal of the amplifiers 252 and 254 of the second amplifying circuit 250 is steered to the second antenna 282. In this example, the first amplifying circuit 220 and the second amplifying circuit 250 may operate as independent amplifiers transmitting on the first antenna 280 and the second antenna 282, respectively.

In the third input switch configuration, the control circuit 295 causes the first input switching network 910 to couple the first output 292 of the transmit circuit 290 to the first port 612 of the first input hybrid coupler 610 and couple the termination load 626 to the second port 614 of the first input hybrid coupler 610. This causes the first output hybrid coupler 630 to steer the combined output signal of the amplifiers 222 and 224 to the third port 636. Also, the control circuit 295 causes the second input switching network 920 to couple the second output 294 of the transmit circuit 290 to the second port 644 of the second input hybrid coupler 640 and couple the termination load 656 to the first port 642 of the second input hybrid coupler 640. This causes the second output hybrid coupler 660 to steer the combined output signal of the amplifiers 252 and 254 to the fourth port 668.

In the example in FIG. 9C, the fourth port 638 of the first output hybrid coupler 630 is coupled to the termination load 628 and the third port 666 of the second output hybrid coupler 660 is coupled to the termination load 658 (e.g., by having the control circuit 295 open the third switch sw3 and the fourth switch sw4 and close the first switch sw1 and the second switch sw2).

In the third input switch configuration, the first amplifying circuit 220 and the second amplifying circuit 250 may operate as independent balanced amplifiers. In this example, the first amplifying circuit 220 amplifies the first RF signal and the first output hybrid coupler 630 outputs the amplified first RF signal at the third port 636 for transmission via the first antenna 280. Also, the second amplifying circuit 250 amplifies the second RF signal and the second output hybrid coupler 660 outputs the amplified second RF signal at the fourth port 668 for transmission via the second antenna 282.

It is to be appreciated that the present disclosure is not limited to the example shown in FIG. 9C. For example, FIG. 9D shows an example in which the switching network 270 includes the fifth switch sw5 coupled between the fourth port 638 of the first output hybrid coupler 630 and ground. In this example, the switching network 270 also includes a sixth switch sw6 coupled between the third port 666 of the second output hybrid coupler 660 and ground. In this example, in the third input switch configuration, the control circuit 295 may open the switches sw1, sw2, sw3, and sw4 and close the switches sw5 and sw6. As a result, the fourth port 638 of the first output hybrid coupler 630 is coupled to ground and the third port 666 of the second output hybrid coupler 660 is coupled to ground.

In the example shown in FIG. 9D, the first amplifying circuit 220 and the second amplifying circuit 250 may operate as independent Doherty amplifiers in which the output signal of the first amplifying circuit 220 is transmitted via the first antenna 280 and the output signal of the second amplifying circuit 250 is transmitted via the second antenna 280. When the first amplifying circuit 220 and the second amplifying circuit 250 operate as independent balanced amplifiers in the third input switch configuration, the control circuit 295 may open the switches sw3, sw4, sw5, and sw6, and close the switches sw1 and sw2 to couple the fourth port 638 of the first output hybrid coupler 630 to the termination load 628 and couple the third port 666 of the second output hybrid coupler 660 to the termination load 658.

In another example, the control circuit 296 may open the switches sw1, sw2, sw3, sw4, sw5, and sw6 in the third input switch configuration. In this example, the fourth port 638 of the first output hybrid coupler 630 is open and the third port 666 of the second output hybrid coupler 660 is open in the third input switch configuration.

FIG. 9E shows an exemplary implementation of the first transmit switch 950 and the second transmit switch 955 according to certain aspects. In this example, the first transmit switch 950 includes a seventh switch sw7 coupled between the third port 636 of the first output hybrid coupler 630 and the first antenna 280 and an eighth switch sw8 coupled between the third port 636 of the first output hybrid coupler 630 and a termination load 960 (e.g., 50 Ohm load). The second transmit switch 955 includes a ninth switch sw9 coupled between the fourth port 668 of the second output hybrid coupler 660 and the second antenna 282 and a tenth switch sw10 coupled between the fourth port 668 of the second output hybrid coupler 660 and a termination load 965 (e.g., 50 Ohm load). The on/off states of the switches sw7, sw8, sw9, and sw10 may be controlled by the control circuit 295.

As discussed above with reference to FIG. 9A, in the first input switch configuration, the fourth port 668 of the second output hybrid coupler 660 may be coupled to a termination load (e.g., 50 Ohm load), shorted to ground, or open. In this regard, FIG. 9E shows an example in which the control circuit 295 opens the switch sw9 and closes the switch sw10 to couple the fourth port 668 of the second output hybrid coupler 660 to the termination load 965 in the first input switch configuration. The control circuit 295 also closes the switch sw7 and opens the switch sw8 to couple the third port 636 of the first output hybrid coupler 630 to the first antenna 280.

As discussed above with reference to FIG. 9B, in the second input switch configuration, the third port 636 of the first output hybrid coupler 630 may be coupled to a termination load (e.g., 50 Ohm load), shorted to ground, or open. In this regard, FIG. 9F shows an example in which the control circuit 295 opens the switch sw7 and closes the sw8 to couple the third port 636 of the first output hybrid coupler 630 to the termination load 960 in the second input switch configuration. The control circuit 295 also closes the switch sw9 and opens the switch sw10 to couple the fourth port 668 of the second output hybrid coupler 660 to the second antenna 282.

In the third input switch configuration, the control circuit 295 may close the switches sw7 and sw9 and open the switches sw8 and sw10 to couple the third port 636 of the first output hybrid coupler 630 to the first antenna 280 and couple the fourth port 668 of the second output hybrid coupler 660 to the second antenna 282.

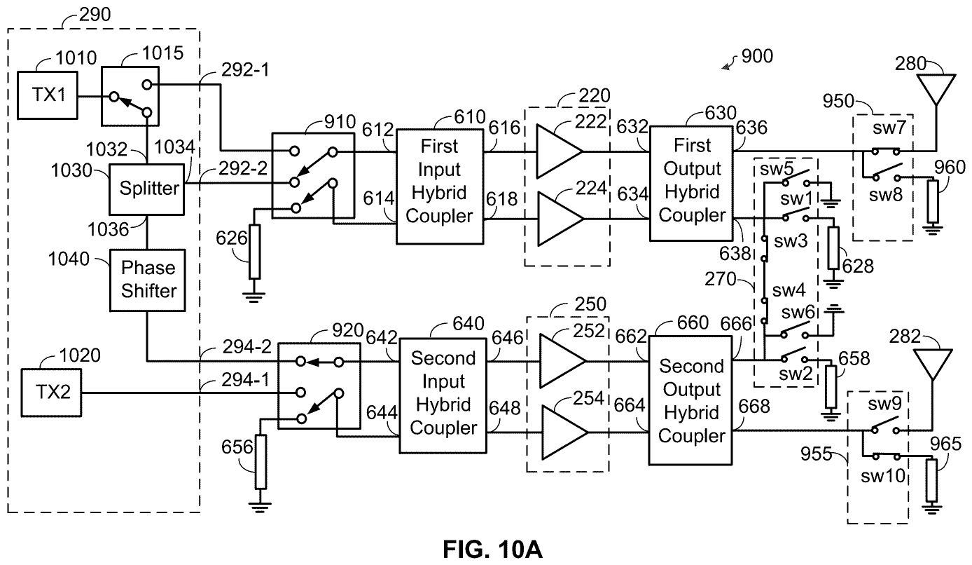

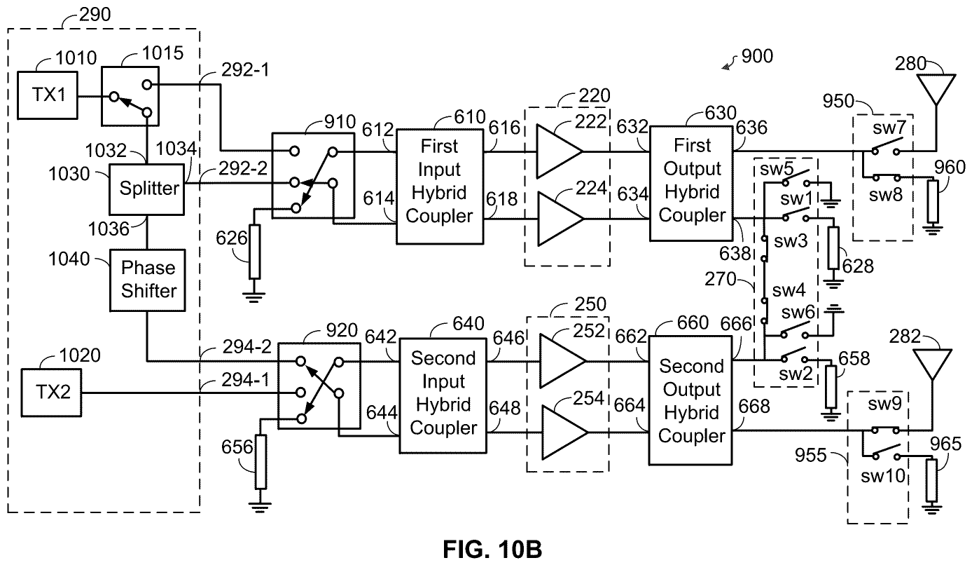

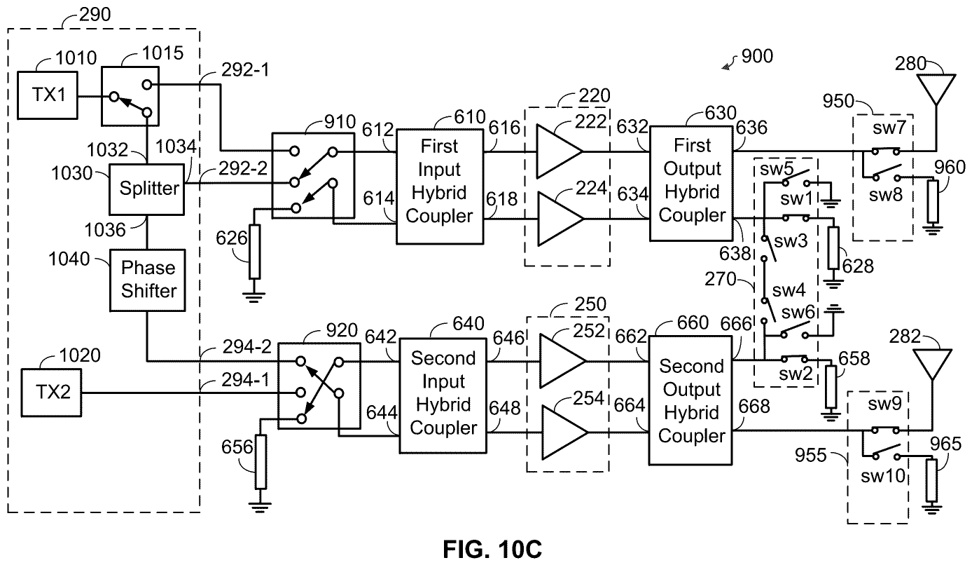

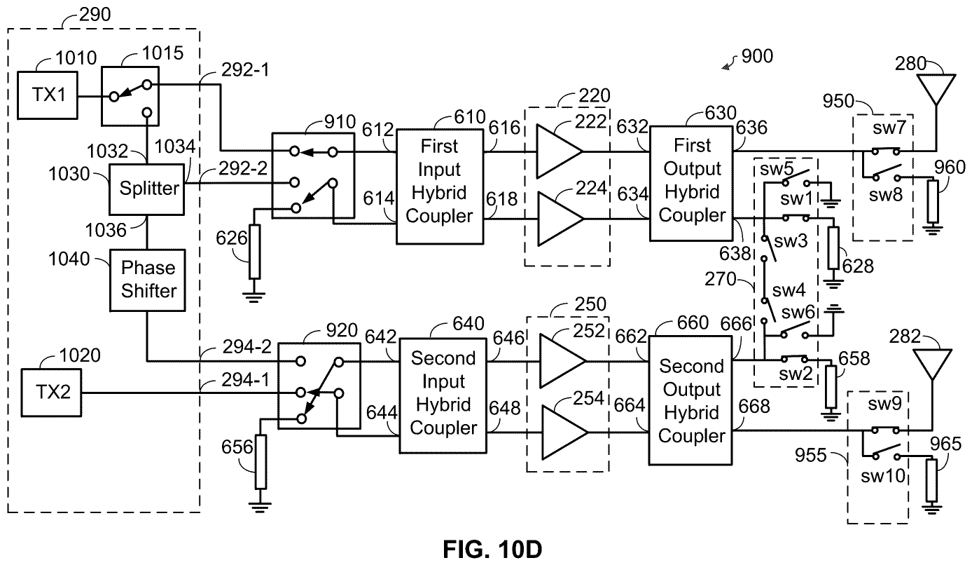

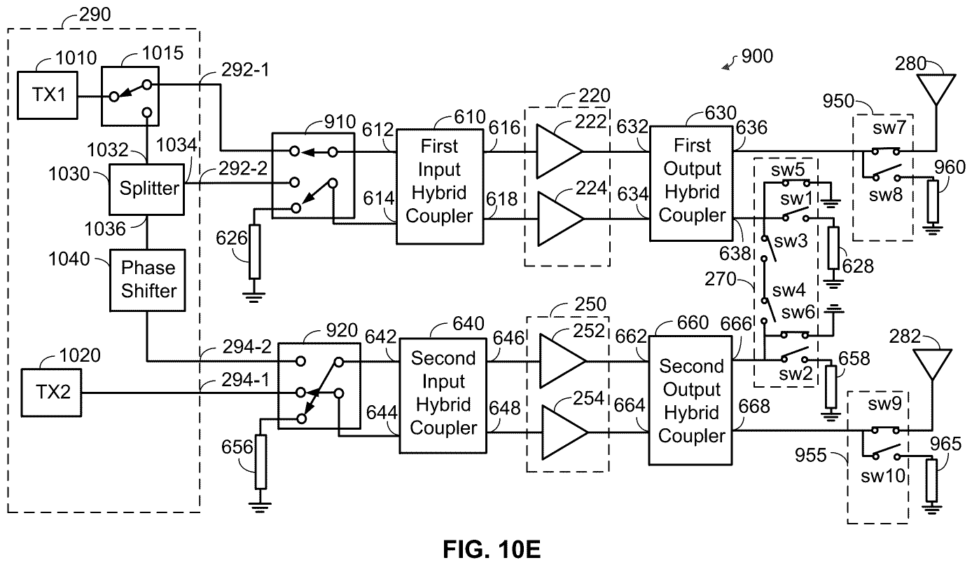

FIGS. 10A to 10E show an exemplary implementation of the transmit circuit 290 according to certain aspects. In this example, the transmit circuit 290 includes a first transmit chain 1010, a second transmit chain 1020, a switching circuit 1015, a splitter 1030, and a phase shifter 1040.

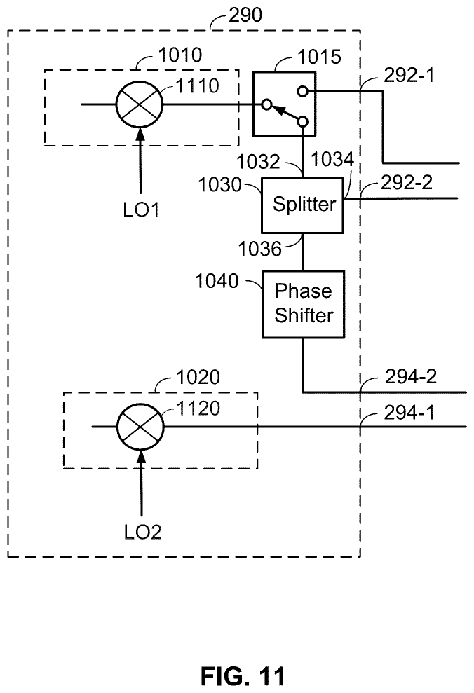

The first transmit chain 1010 is configured to generate a first RF signal and the second transmit chain 1020 is configured to generate a second RF signal. Each of the transmit chains 1010 and 1020 may be implemented with an SDR, hardware, or a combination of both. For example, the first transmit chain 1010 may frequency upconvert a first baseband signal into the first RF signal by mixing the first baseband signal with a first local oscillator signal, and the second transmit chain 1020 may frequency upconvert a second baseband signal into the second RF signal by mixing the second baseband signal with a second local oscillator signal. In this regard, FIG. 11 shows an example in which the first transmit chain 1010 includes a first mixer 1110 configured to mix the first baseband signal with the first local oscillator signal (labeled “LO1”) to generate the first RF signal and the second transmit chain 1020 includes a second mixer 1120 configured to mix the second baseband signal with the second local oscillator signal (labeled “LO2”) to generate the second RF signal. The first local oscillator signal and the second local oscillator signal may have the same frequency or different frequencies. The first and second baseband signals may be generated by a baseband processor (not shown).

In this example, the first output 292 of the transmit circuit 290 includes outputs 292-1 and 292-2 coupled to the first input switching network 910, and the second output 294 of the transmit circuit 290 includes outputs 294-1 and 294-2 coupled to the second input switching network 920. The switching circuit 1015 is coupled to the first transmit chain 1010, the output 292-1, and the splitter 1030. The switching circuit 1015 is configured to selectively couple the first transmit chain 1010 to the output 292-1 or the splitter 1030. The second transmit chain 1020 is coupled to the output 294-1.

The splitter 1030 has an input 1032 coupled to the first transmit chain 1010, a first output 1034 coupled to the output 292-2, and a second output 1036 coupled to the phase shifter 1040. The splitter 1030 is configured to receive the first RF signal from the first transmit chain 1010 at the input 1032 and split the first RF signal between the first output 1034 coupled to the output 292-2 and the second output 1036 coupled to the phase shifter 1040. For example, the splitter 1030 may be implemented with a power splitter configured to split the power of the first RF signal evenly between the first output 1034 and the second output 1036. However, it is to be appreciated that the present disclosure is not limited to this example.

The phase shifter 1040 is coupled between the second output 1036 of the splitter 1030 and the output 294-2. The phase shifter 1040 is configured to shift the phase of the first RF signal from the splitter 1030 and output the resulting phase-shifted version of the first RF signal to the output 294-2. In this example, the phase shifter 1040 provides a phase shift between the output 292-2 and the output 294-2, which are coupled to the first input switching network 910 and the second input switching network 920, respectively.

FIG. 10A shows an exemplary configuration according to certain aspects. In this configuration, the control circuit 295 causes the switching circuit 1015 to couple the first RF chain 1010 to the splitter 1030. The control circuit 295 also causes the first input switching network 910 to couple the first port 612 of the first input hybrid coupler 610 to the output 292-2 of the transmit circuit 290 and couple the second port 614 of the first input hybrid coupler 610 to the termination load 626. The control circuit 295 also causes the second input switching network 920 to couple the first port 642 of the second input hybrid coupler 640 to the output 294-2 of the transmit circuit 290 and couple the second port 644 of the second input hybrid coupler 640 to the termination load 656. The control circuit 295 also closes the switches sw3, sw4, sw7, and sw10 and opens the switches sw1, sw2, sw5, sw6, sw8, and sw9, as shown in FIG. 10A.

In this configuration, the splitter 1030 splits the first RF signal between the output 292-2 and the phase shifter 1040 and the phase shifter 1040 shifts the phase of the first RF signal and outputs the phase-shifted version of the first RF signal to the output 294-2. The first input switching network 910 couples the first RF signal to the first port 612 of the first input hybrid coupler 610 and the second input switching network 920 couples the phase-shifted version of the first RF signal to the first port 642 of the second input hybrid coupler 640. In this example, the first amplifying circuit 220 amplifies the first RF signal and the second amplifying circuit 250 amplifies the phase-shifted version of the first RF signal. The second output hybrid coupler 660 injects the output signal of the second amplifying circuit 250 into the first output hybrid coupler 630, which combines the output signals of the first amplifying circuit 220 and the second amplifying circuit 250 and outputs the combined output signal to the first antenna 280 for transmission. In this configuration, the system 900 may operate as a LMBA, as discussed above. In this example, the control circuit 295 may set the phase shift of the phase shifter 1040 to a phase shift that provides high power efficiency when the system 900 is operated as the LMBA, as discussed above with reference to FIG. 6B.

FIG. 10B shows another exemplary configuration in which the combined output signal is steered to the second antenna 282 instead of the first antenna 280 using the input switching networks 910 and 920. In this configuration, the control circuit 295 causes the switching circuit 1015 to couple the first RF chain 1010 to the splitter 1030. The control circuit 295 also causes the first input switching network 910 to couple the second port 614 of the first input hybrid coupler 610 to the output 292-2 of the transmit circuit 290 and couple the first port 612 of the first input hybrid coupler 610 to the termination load 626. The control circuit 295 also causes the second input switching network 920 to couple the second port 644 of the second input hybrid coupler 640 to the output 294-2 of the transmit circuit 290 and couple the first port 642 of the second input hybrid coupler 640 to the termination load 656. The control circuit 295 also closes the switches sw3, sw4, sw8, and sw9 and opens the switches sw1, sw2, sw5, sw6, sw7, and sw10, as shown in FIG. 10B.

In this configuration, the splitter 1030 splits the first RF signal between the output 292-2 and the phase shifter 1040 and the phase shifter 1040 shifts the phase of the first RF signal and outputs the phase-shifted version of the first RF signal to the output 294-2. The first input switching network 910 couples the first RF signal to the second port 614 of the first input hybrid coupler 610 and the second input switching network 920 couples the phase-shifted version of the first RF signal to the second port 644 of the second input hybrid coupler 640. In this example, the first amplifying circuit 220 amplifies the first RF signal and the second amplifying circuit 250 amplifies the phase-shifted version of the first RF signal. The first output hybrid coupler 630 injects the output signal of the first amplifying circuit 220 into the second output hybrid coupler 660, which combines the output signals of the first amplifying circuit 220 and the second amplifying circuit 250 and outputs the combined output signal to the second antenna 282 for transmission.

FIG. 10C shows another exemplary configuration in which the output signal of the first amplifying circuit 220 is transmitted via the first antenna 280 and the output signal of the second amplifying circuit 250 is transmitted via the second antenna 282. In this configuration, the control circuit 295 causes the switching circuit 1015 to couple the first RF chain 1010 to the splitter 1030. The control circuit 295 also causes the first input switching network 910 to couple the first port 612 of the first input hybrid coupler 610 to the output 292-2 of the transmit circuit 290 and couple the second port 614 of the first input hybrid coupler 610 to the termination load 626. The control circuit 295 also causes the second input switching network 920 to couple the second port 644 of the second input hybrid coupler 640 to the output 294-2 of the transmit circuit 290 and couple the first port 642 of the second input hybrid coupler 640 to the termination load 656. The control circuit 295 also closes the switches sw1, sw2, sw7, and sw9 and opens the switches sw3, sw4, sw5, sw6, sw8, and sw10, as shown in FIG. 10C.

In this configuration, the splitter 1030 splits the first RF signal between the output 292-2 and the phase shifter 1040 and the phase shifter 1040 shifts the phase of the first RF signal and outputs the phase-shifted version of the first RF signal to the output 294-2. The first input switching network 910 couples the first RF signal to the first port 612 of the first input hybrid coupler 610 and the second input switching network 920 couples the phase-shifted version of the first RF signal to the second port 644 of the second input hybrid coupler 640. In this example, the first amplifying circuit 220 amplifies the first RF signal and the second amplifying circuit 250 amplifies the phase-shifted version of the first RF signal. The first output hybrid coupler 630 outputs the output signal of the first amplifying circuit 220 to the first antenna 280 for transmission and the second output hybrid coupler 660 outputs the output signal of the second amplifying circuit to the second antenna 282 for transmission.

In this example, the first RF signal amplified by the first amplifying circuit 220 is transmitted via the first antenna 280 and the phase-shifted version of the first RF signal amplified by the second amplifying circuit 250 is transmitted via the second antenna 282. This configuration may be used, for example, for beamforming. In this example, the control circuit 295 may adjust the phase shift of the phase shifter 1040 to adjust the angle of the transmission beam.

FIG. 10D shows another exemplary configuration in which the output signal of the first amplifying circuit 220 is transmitted via the first antenna 280 and the output signal of the second amplifying circuit 250 is transmitted via the second antenna 282. In this configuration, the control circuit 295 causes the switching circuit 1015 to couple the first RF chain 1010 to the output 292-1. The control circuit 295 also causes the first input switching network 910 to couple the first port 612 of the first input hybrid coupler 610 to the output 292-1 of the transmit circuit 290 and couple the second port 614 of the first input hybrid coupler 610 to the termination load 626. The control circuit 295 also causes the second input switching network 920 to couple the second port 644 of the second input hybrid coupler 640 to the output 294-1 of the transmit circuit 290 and couple the first port 642 of the second input hybrid coupler 640 to the termination load 656. The control circuit 295 also closes the switches sw1, sw2, sw7, and sw9 and opens the switches sw3, sw4, sw5, sw6, sw8, and sw10, as shown in FIG. 10D.

In this configuration, the first input switching network 910 couples the first RF signal from the first RF chain 1010 to the first port 612 of the first input hybrid coupler 610 and the second input switching network 920 couples the second RF signal from the second RF chain 1020 to the second port 644 of the second input hybrid coupler 640. In this example, the first amplifying circuit 220 amplifies the first RF signal and the second amplifying circuit 250 amplifies the second RF signal. The first output hybrid coupler 630 outputs the output signal of the first amplifying circuit 220 to the first antenna 280 for transmission and the second output hybrid coupler 660 outputs the output signal of the second amplifying circuit to the second antenna 282 for transmission.

In this example, the first RF signal amplified by the first amplifying circuit 220 is transmitted via the first antenna 280 and the second RF signal amplified by the second amplifying circuit is transmitted via the second antenna 282. In this configuration, the fourth port 638 of the first output hybrid coupler 630 is coupled to the termination load 628 and the third port 666 of the second output hybrid coupler 660 is coupled to the termination load 658. This configuration may be used, for example, to operate the amplifying circuits 220 and 250 as independent balance amplifiers.

FIG. 10E shows another configuration in which the switch configurations of the input switching networks 910 and 920 are the same as in FIG. 10D. In this configuration, the control circuit 295 opens the switch sw1 and closes the switch sw5 to couple the fourth port 638 of the first output hybrid coupler 630 to ground instead of the termination load 628 shown in FIG. 10D. The control circuit 295 also opens the switch sw2 and the closes the switch sw6 to couple the third port 666 of the second output hybrid coupler 660 to ground instead of the termination load 658 shown in FIG. 10D. The control circuit 295 also closes the switches sw7 and sw9 and opens the switches sw3, sw4, sw8, and sw10, as shown in 10E. This configuration may be used, for example, to operate the amplifying circuits 220 and 250 as independent Doherty amplifiers.

It is to be appreciated that one or more of the switches shown in the examples in FIGS. 9A to 9F and 10A to 10E may be omitted, for example, for implementations where one or more of the exemplary configurations discussed above are not used. It is also to be appreciated that the termination load 626 may be omitted in some implementations. In these implementations, the omission of the termination load 626 may reduce the area of the system 900 at the expense of lower isolation between the ports 616 and 618 of the first input hybrid coupler 610. Similarly, the termination load 656 may be omitted in some implementations.

It is also to be appreciated that the exemplary implementation of the transmit circuit 290 shown in the examples in FIG. 10A to 10E may also be used in the examples shown in FIGS. 6A to 6D. For example, in some implementations, the first output 1034 of the splitter 1030 may be coupled to the first port 612 of the first input hybrid coupler 610 and the phase shifter 1040 may be coupled between the second output 1036 of the splitter 1030 and the first port 642 of the second input hybrid coupler 640 in the examples in FIGS. 6A to 6D.

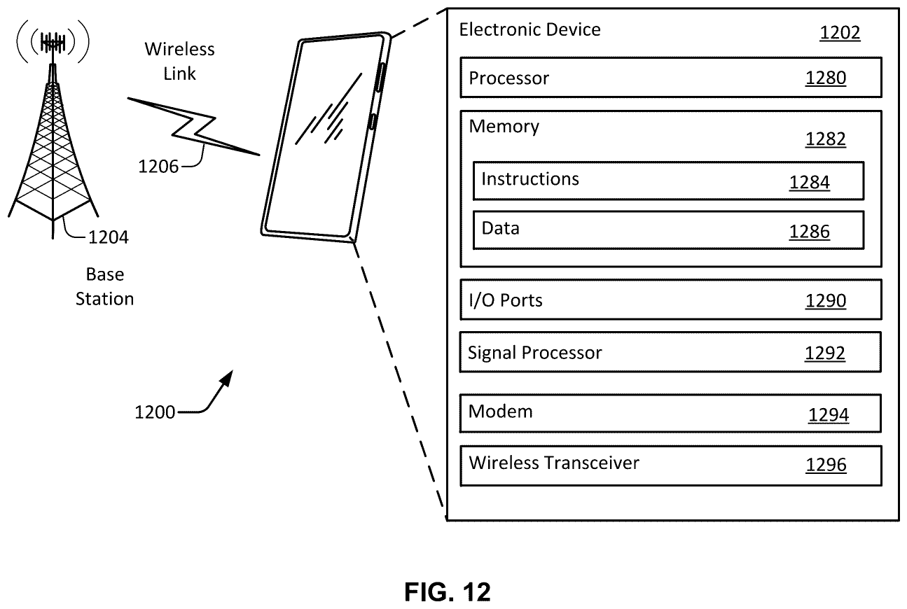

FIG. 12 is a diagram of an environment 1200 that includes a wireless device 1202 and a base station 1204. In the environment 1200, the wireless device 1202 communicates with the base station 1204 via a wireless link 1206. As shown, the wireless device 1202 is depicted as a smart phone. However, it is to be understood that the wireless device 1202 may be implemented as any suitable wireless device, such as a cellular base station, a broadband router, an access point, a cellular or mobile phone, a gaming device, a navigation device, a media device, a laptop computer, a desktop computer, a tablet computer, a server computer, a network-attached storage (NAS) device, a smart appliance, a vehicle-based communication system, an Internet of Things (IoT) device, a sensor or security device, an asset tracker, and so forth.

The base station 1204 communicates with the wireless device 1202 via the wireless link 1206, which may be implemented as any suitable type of wireless link. Although depicted as a base station tower of a cellular radio network, the base station 1204 may represent or be implemented as another device, such as a satellite, a terrestrial broadcast tower, an access point, a peer-to-peer device, a mesh network node, and so forth. The wireless link 1206 may include a downlink of data and/or control information communicated from the base station 1204 to the wireless device 1202 and an uplink of other data and/or control information communicated from the wireless device 1202 to the base station 1204. The wireless link 1206 may be implemented using any suitable communication protocol or standard, such as 3rd Generation Partnership Project Long-Term Evolution (3GPP LTE, 3GPP NR 5G), IEEE 1002.99, IEEE 1002.99, Bluetooth™, and so forth.

The wireless device 1202 includes a processor 1280 and a memory 1282. The memory 1282 may be or form a portion of a computer readable storage medium. The processor 1280 may include any type of processor, such as an application processor or a multi-core processor, that is configured to execute processor-executable instructions stored in the memory 1282. The memory 1282 may include any suitable type of data storage media, such as a volatile memory (e.g., random access memory (RAM)), a non-volatile memory (e.g., Flash memory), an optical media, a magnetic media (e.g., disk or tape), or any combination thereof. In the context of this disclosure, the memory 1282 may store instructions 1284, data 1286, and other information of the wireless device 1202.

The wireless device 1202 may also include input/output (I/O) ports 1290. The I/O ports 1290 enable data exchanges or interaction with other devices, networks, or users or between components of the wireless device 1202.

The wireless device 1202 may further include a signal processor (SP) 1292 (e.g., such as a digital signal processor (DSP)). The signal processor 1292 may function similar to the processor 1280 and may be capable of executing instructions and/or processing information in conjunction with the memory 1282.

For communication purposes, the wireless device 1202 also includes a modem 1294, a wireless transceiver 1296, and one or more antennas (e.g., the antennas 280 and 282). The wireless transceiver 1296 may include the amplifying circuits 220 and 250, the input hybrid couplers 610 and 640, the output hybrid couplers 630 and 660, the transmit circuit 290, the control circuit 295, the input switching networks 910 and 920, the baluns 210, 230, 240, and 260 and/or the switching network 270. The wireless transceiver 1296 provides connectivity to respective networks (e.g., the base station 1204) and other wireless devices connected therewith using RF signals. The wireless transceiver 1296 may facilitate communication over any suitable type of wireless network, such as a wireless local area network (LAN) (WLAN), a peer-to-peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

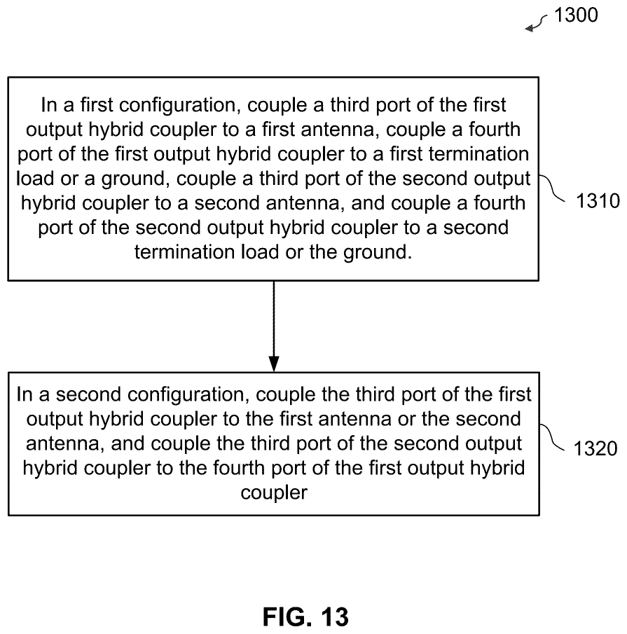

FIG. 13 shows an example of a method 1300 for wireless communications in a system according to certain aspects. The system includes a first amplifier (e.g., the first amplifier 222), a second amplifier (e.g., the second amplifier 224), a first output hybrid coupler (e.g., the first output hybrid coupler 630) having a first port coupled to an output of the first amplifier and a second port coupled to an output of the second amplifier, a third amplifier (e.g., the third amplifier 252), a fourth amplifier (e.g., the fourth amplifier 254), and a second output hybrid coupler (e.g., the second output hybrid coupler 660) having a first port coupled to an output of the third amplifier and a second port coupled to an output of the fourth amplifier.

At block 1310, in a first configuration, a third port of the first output hybrid coupler is coupled to a first antenna, a fourth port of the first output hybrid coupler is coupled a first termination load or a ground, a third port of the second output hybrid coupler is coupled to a second antenna, and a fourth port of the second output hybrid coupler is coupled to a second termination load or the ground. For example, the first antenna may correspond to the first antenna 280 and the second antenna by correspond to the second antenna 282. The third port of the first output hybrid coupler may be coupled to the first antenna by the antenna select switch 275 or the switch sw7. The fourth port of the first output hybrid coupler may be coupled to the first termination load (e.g., termination load 628) or the ground by the switch sw1 or the switch sw5. The third port of the second output hybrid coupler may be coupled to the second antenna by the antenna select switch 275 and/or the switch sw2. The fourth port of the second output hybrid coupler may be coupled to the second terminational load (e.g., termination load 658) or the ground by the switch sw6 or the switch sw7.

At block 1320, in a second configuration, the third port of the first output hybrid coupler is coupled to the first antenna or the second antenna, and the third port of the second output hybrid coupler is coupled to the fourth port of the first output hybrid coupler. For example, the third port of the first output hybrid coupler may be coupled to the first antenna or the second antenna by the antenna select switch 275 and the third port of the second output hybrid coupler may be coupled to the fourth port of the first output hybrid coupler by the switching network 270.

The method 1300 may also include, in the second configuration, coupling the fourth port of the second output hybrid coupler to the second termination load.

In certain aspects, the system may also include a first input hybrid coupler (e.g., the first input hybrid coupler 610) having a first port, a second port coupled to a third termination load (e.g., termination load 626), a third port coupled to an input of the first amplifier, and the fourth port coupled to an input of the second amplifier, and a second input hybrid coupler (e.g., second input hybrid coupler 640) having a first port, a second port coupled to a fourth termination load (e.g., termination load 656), a third port coupled to an input of the third amplifier, and a fourth port coupled to an input of the fourth amplifier. In these aspects, the method 1300 may further include inputting a first radio frequency (RF) signal to the first port of the first input hybrid coupler, and inputting a second RF signal to the first port of the second input hybrid coupler. The first RF signal and the second RF signal may be input by the transmit circuit 290, the first input switching network 910, and/or the second input switching network 920. In certain aspects, the second RF signal includes a phase-shifted version of the first RF signal. For example, the phase-shifted version of the first RF signal may be generated by the phase shifter 1040.

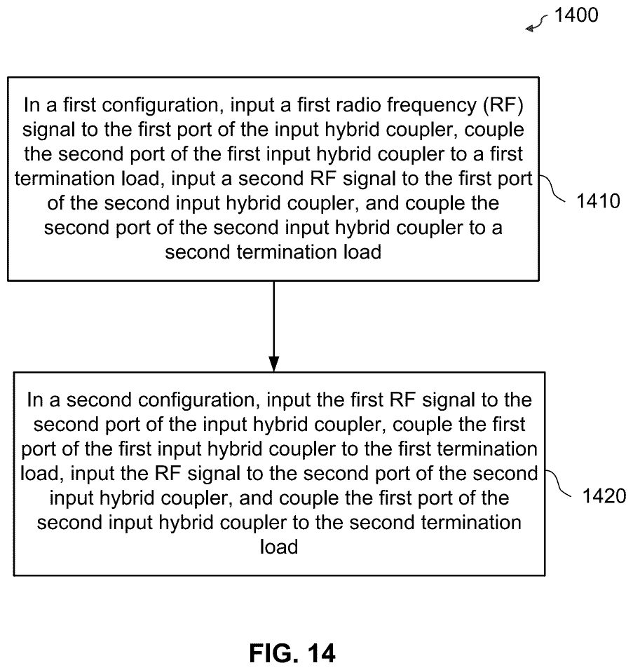

FIG. 14 shows another example of a method 1400 for wireless communications in a system. The system include a first amplifier (e.g., the amplifier 222), a second amplifier (e.g., the amplifier 224), a first input hybrid coupler (e.g., the first input hybrid coupler 610) having a first port, a second port, a third port coupled to an input of the first amplifier, and a fourth port coupled to an input of the second amplifier, a third amplifier (e.g., the amplifier 252), a fourth amplifier (e.g., the amplifier 254), and a second input hybrid coupler (e.g., second input hybrid coupler 640) having a first port, a second port, a third port coupled to an input of the third amplifier, and a fourth port coupled to an input of the fourth amplifier.

At block 1410, in a first configuration, a first radio frequency (RF) signal is input to the first port of the first input hybrid coupler, the second port of the first input hybrid coupler is coupled to a first termination load, a second input RF signal is input to the first port of the second input hybrid coupler, and the second port of the second input hybrid coupler is coupled to a second termination load. For example, the first input switching network 910 may input the first RF signal to the first port of the first input hybrid coupler and couple the second port of the first input hybrid coupler to the first termination load (e.g., termination load 626). The second input switching network 920 may input the second RF signal to the first port of the first input hybrid coupler and couple the second port of the second input hybrid coupler to the second termination load (e.g., termination load 656).

At block 1420, in a second configuration, the first RF signal is input to the second port of the first input hybrid coupler, the first port of the first input hybrid coupler is coupled to the first termination load, the second input RF signal is input to the second port of the second input hybrid coupler, and the first port of the second input hybrid coupler is coupled to the second termination load. For example, the first input switching network 910 may input the first RF signal to the second port of the first input hybrid coupler and couple the first port of the first input hybrid coupler to the first termination load (e.g., termination load 626). The second input switching network 920 may input the second RF signal to the second port of the first input hybrid coupler and couple the first port of the second input hybrid coupler to the second termination load (e.g., termination load 656).

The method 1400 may also include, in a third configuration, inputting the first RF signal to the first port of the first input hybrid coupler, coupling the second port of the first input hybrid coupler to the first termination load, inputting the second input RF signal to the second port of the second input hybrid coupler, and coupling the first port of the second input hybrid coupler to the second termination load.

In certain aspects, the system further comprises a first output hybrid coupler (e.g., first output hybrid coupler 630) having a first port coupled to an output of the first amplifier and a second port coupled to an output of the second amplifier, and a second output hybrid coupler (e.g., second output hybrid coupler 660) having a first port coupled to an output of the third amplifier and a second port coupled to an output of the fourth amplifier. In these aspects, the method 1400 may furth include, in the first configuration, coupling the third port of the first output hybrid coupler to a first antenna, and coupling the third port of the second output hybrid coupler to the fourth port of the first output hybrid coupler, and, in the second configuration, coupling the fourth port of the second output hybrid coupler to a second antenna, and coupling the third port of the second output hybrid coupler to the fourth port of the first output hybrid coupler. For example, the switching network 270 may couple the third port of the second output hybrid coupler to the fourth port of the first output hybrid coupler, the switch sw7 may couple the third port of the first output hybrid coupler to the first antenna, and the switch sw9 may couple the fourth port of the second output hybrid coupler to the second antenna.

The method 1400 may further include, in a third configuration, inputting the first RF signal to the first port of the first input hybrid coupler, coupling the second port of the first input hybrid coupler to the first termination load, inputting the second input RF signal to the second port of the second input hybrid coupler, coupling the first port of the second input hybrid coupler to the second termination load, coupling the third port of the first output hybrid coupler to the first antenna, and coupling the fourth port of the second output hybrid coupler to the second antenna.

The control circuit 295 may be implemented with a general-purpose processor, a digital signal processor (DSP), an application specific integrated circuit (ASIC), a field programmable gate array (FPGA) or other programmable logic device, a digital finite state machine (FSM), discrete hardware components (e.g., logic gates), or any combination thereof designed to perform the functions described herein. A processor may perform the functions described herein by executing software comprising code for performing the functions. The software may be stored on a computer-readable storage medium, such as a RAM, a ROM, an EEPROM, an optical disk, and/or a magnetic disk.

Implementation examples are described in the following numbered clauses:
1. A system, comprising:
   a first amplifier;
   a second amplifier;
   a first output hybrid coupler having a first port, a second port, a third port, and a fourth port, wherein the first port of the first output hybrid coupler is coupled to an output of the first amplifier, and the second port of the first output hybrid coupler is coupled to an output of the second amplifier;
   a third amplifier;
   a fourth amplifier;
   a second output hybrid coupler having a first port, a second port, a third port, and a fourth port, wherein the first port of the second output hybrid coupler is coupled to an output of the third amplifier, and the second port of the second output hybrid coupler is coupled to an output of the fourth amplifier; and
   a switching network coupled between the fourth port of the first output hybrid coupler and the third port of the second output hybrid coupler.
2. The system of clause 1, wherein the third port of the first output hybrid coupler is coupled to a first antenna, and the fourth port of the second output hybrid coupler is coupled to a first termination load or a ground.
3. The system of clause 2, wherein the switching network comprises:
   a first switch coupled between the fourth port of the first output hybrid coupler and a second termination load or between the forth port of the first output hybrid coupler and the ground;
   a second switch coupled between the third port of the second output hybrid coupler and a second antenna; and
   at least one switch coupled between the fourth port of the first output hybrid coupler and the third port of the second output hybrid coupler.
4. The system of clause 3, further comprising a control circuit configured to:
   in a first configuration, close the first switch, close the second switch, and open the at least one switch; and
   in a second configuration, open the first switch, open the second switch, and close the at least one switch.
5. The system of clause 4, wherein, in the first configuration, the first amplifier and the second amplifier operate as a first balanced amplifier, and the third amplifier and the fourth amplifier operate as a second balanced amplifier.
6. The system of clause 4, wherein, in the first configuration, the first amplifier and the second amplifier operate as a first Doherty amplifier, and the third amplifier and the fourth amplifier operate as a second Doherty amplifier.
7. The system of clause 1, further comprising an antenna select switch, wherein the third port of the first output hybrid coupler is coupled to the antenna select switch, the fourth port of the second output hybrid coupler is coupled to a first termination load or a ground, and the antenna select switch is configured to selectively couple the third port of the first output hybrid coupler to a first antenna or a second antenna.
8. The system of clause 7, wherein the switching network comprises:
   a first switch coupled between the fourth port of the first output hybrid coupler and a second termination load or between the forth port of the first output hybrid coupler and the ground;
   a second switch coupled between the third port of the second output hybrid coupler and the antenna select switch; and
   at least one switch coupled between the fourth port of the first output hybrid coupler and the third port of the second output hybrid coupler.
9. The system of clause 8, further comprising a control circuit configured to:
   in a first configuration, close the first switch, close the second switch, and open the at least one switch; and
   in a second configuration, open the first switch, open the second switch, and close the at least one switch.
10. The system of clause 9, wherein, in the first configuration, the antenna select switch is configured to selectively couple the third port of the second output hybrid coupler to the first antenna or the second antenna.
11. The system of any one of clauses 1 to 10, further comprising:
   a transmit circuit;
   a first input hybrid coupler having a first port, a second port, a third port, and a fourth port, wherein the first port of the first input hybrid coupler is coupled to the transmit circuit, the third port of the first input hybrid coupler is coupled to an input of the first amplifier, and the fourth port of the first input hybrid coupler is coupled to an input of the second amplifier; and
   a second input hybrid coupler having a first port, a second port, a third port, and a fourth port, wherein the first port of the second input hybrid coupler is coupled to the transmit circuit, the third port of the second input hybrid coupler is coupled to an input of the third amplifier, and the fourth port of the second input hybrid coupler is coupled to an input of the fourth amplifier.
12. The system of clause 11, further comprising:
   a first termination load coupled the second port of the first input hybrid coupler; and
   a second termination load coupled to the second port of the second input hybrid coupler.
13. The system of clause 11 or 12, wherein the transmit circuit is configured to:
   output a first radio frequency (RF) signal to the first port of the first input hybrid coupler; and
   output a second RF signal to the first port of the second input hybrid coupler.
14. The system of any one of clauses 11 to 13, wherein the transmit circuit comprises:
   a splitter having an input, a first output, and a second output, wherein the splitter is configured to receive a radio frequency (RF) signal at the input of the splitter and split the RF signal between the first output of the splitter and the second output of the splitter, and wherein the first port of the first input hybrid coupler is coupled to the first output of the splitter; and
   a phase shifter coupled between the second output of the splitter and the first port of the second input hybrid coupler.
15. The system of any one of clauses 1 to 10, further comprising:
   a transmit circuit;
   a first input hybrid coupler having a first port, a second port, a third port, and a fourth port, wherein the third port of the first input hybrid coupler is coupled to an input of the first amplifier, and the fourth port of the first input hybrid coupler is coupled to an input of the second amplifier;
   a first input switching network coupled to the transmit circuit, the first port of the first input hybrid coupler, and the second port of the first input hybrid coupler, wherein the first input switching network is configured to selectively couple the transmit circuit to the first port of the first input hybrid coupler or the second port of the first input hybrid coupler;
   a second input hybrid coupler having a first port, a second port, a third port, and a fourth port, wherein the third port of the second input hybrid coupler is coupled to an input of the third amplifier, and the fourth port of the second input hybrid coupler is coupled to an input of the fourth amplifier; and
   a second input switching network coupled to the transmit circuit, the first port of the second input hybrid coupler, and the second port of the second input hybrid coupler, wherein the second input switching network is configured to selectively couple the transmit circuit to the first port of the second input hybrid coupler or the second port of the second input hybrid coupler.
16. The system of clause 15, further comprising:
   a first switch coupled between the third port of the first output hybrid coupler and a first antenna; and
   a second switch coupled between the fourth port of the second output hybrid coupler and a second antenna.
17. The system of clause 16, further comprising a control circuit configured to:
   in a first configuration, cause the first input switching network to couple the transmit circuit to the first port of the first input hybrid coupler, cause the second input switching network to couple the transmit circuit to the first port of the second input hybrid coupler, close the first switch, and open the second switch; and
   in a second configuration, cause the first input switching network to couple the transmit circuit to the second port of the first input hybrid coupler, cause the second input switching network to couple the transmit circuit to the second port of the second input hybrid coupler, open the first switch, and close the second switch.
18. The system of clause 17, wherein the switching network comprises at least one switch coupled between the third port of the second output hybrid coupler and the fourth port of the first output hybrid coupler, and the control circuit is configured to:
   in the first configuration and the second configuration, close the at least one switch; and
   in a third configuration, cause the first input switching network to couple the transmit circuit to the first port of the first input hybrid coupler, cause the second input switching network to couple the transmit circuit to the second port of the second input hybrid coupler, close the first switch, close the second switch, and open the at least one switch.
19. The system of clause 1, wherein the first output hybrid coupler is configured to combine output signals of the first and second amplifiers, and the second output hybrid coupler is configured to combine output signals of the third and fourth amplifiers.
20. A system, comprising:
   a transmit circuit;
   a first amplifier;
   a second amplifier;
   a first input hybrid coupler having a first port, a second port, a third port, and a fourth port, wherein the third port of the first input hybrid coupler is coupled to an input of the first amplifier, and the fourth port of the first input hybrid coupler is coupled to an input of the second amplifier;
   a first input switching network coupled to the transmit circuit, the first port of the first input hybrid coupler, and the second port of the first input hybrid coupler, wherein the first input switching network is configured to selectively couple the transmit circuit to the first port of the first input hybrid coupler or the second port of the first input hybrid coupler;
   a third amplifier;
   a fourth amplifier;
a second input hybrid coupler having a first port, a second port, a third port, and a fourth port, wherein the third port of the second input hybrid coupler is coupled to an input of the third amplifier, and the fourth port of the second input hybrid coupler is coupled to an input of the fourth amplifier; and
   a second input switching network coupled to the transmit circuit, the first port of the second input hybrid coupler, and the second port of the second input hybrid coupler, wherein the second input switching network is configured to selectively couple the transmit circuit to the first port of the second input hybrid coupler or the second port of the second input hybrid coupler.
21. The system of clause 20, further comprising a first termination load coupled to the first input switching network, wherein the first input switching network is configured to selectively couple the first termination load to the first port of the first input hybrid coupler or the second port of the first input hybrid coupler.
22. The system of clause 21, further comprising a control circuit configured to:
   in a first configuration, cause the first input switching network to couple the transmit circuit to the first port of the first input hybrid coupler and couple the first termination load to the second port of the first input hybrid coupler; and
   in a second configuration, cause the first input switching network to couple the transmit circuit to the second port of the first input hybrid coupler and couple the first termination load to the first port of the first input hybrid coupler.
23. The system of clause 21, further comprising a second termination load coupled to the second input switching network, wherein the second input switching network is configured to selectively couple the second termination load to the first port of the second input hybrid coupler or the second port of the second input hybrid coupler.
24. The system of clause 23, further comprising a control circuit configured to:
   in a first configuration, cause the first input switching network to couple the transmit circuit to the first port of the first input hybrid coupler and couple the first termination load to the second port of the first input hybrid coupler;
   in the first configuration, cause the second input switching network to couple the transmit circuit to the first port of the second input hybrid coupler and couple the second termination load to the second port of the second input hybrid coupler;
   in a second configuration, cause the first input switching network to couple the transmit circuit to the second port of the first input hybrid coupler and couple the first termination load to the first port of the first input hybrid coupler; and
   in the second configuration, cause the second input switching network to couple the transmit circuit to the second port of the second input hybrid coupler and couple the second termination load to the first port of the second input hybrid coupler.
25. The system of clause 24, wherein the control circuit is further configured to:
   in a third configuration, cause the first input switching network to couple the transmit circuit to the first port of the first input hybrid coupler and couple the first termination load to the second port of the first input hybrid coupler; and
   in the third configuration, cause the second input switching network to couple the transmit circuit to the second port of the second input hybrid coupler and couple the second termination load to the first port of the second input hybrid coupler.
26. The system of any one of clause 20 to 25, further comprising:
   a first output hybrid coupler having a first port, a second port, a third port, and a fourth port, wherein the first port of the first output hybrid coupler is coupled to an output of the first amplifier, and the second port of the first output hybrid coupler is coupled to an output of the second amplifier; and
   a second output hybrid coupler having a first port, a second port, a third port, and a fourth port, wherein the first port of the second output hybrid coupler is coupled to an output of the third amplifier, the second port of the second output hybrid coupler is coupled to an output of the fourth amplifier.
27. The system of clause 26, further comprising:
   a first switch coupled between the third port of the first output hybrid coupler and a first antenna; and
   a second switch coupled between the fourth port of the second output hybrid coupler and a second antenna.
28. The system of clause 27, further comprising at least one switch coupled between the third port of the second output hybrid coupler and the fourth port of the first output hybrid coupler.
29. The system of clause 28, further comprising a control circuit configured to:
   in a first configuration, cause the first input switching network to couple the transmit circuit to the first port of the first input hybrid coupler, cause the second input switching network to couple the transmit circuit to the first port of the second input hybrid coupler, close the first switch, open the second switch, and close the at least one switch; and
   in a second configuration, cause the first input switching network to couple the transmit circuit to the second port of the first input hybrid coupler, cause the second input switching network to couple the transmit circuit to the second port of the second input hybrid coupler, open the first switch, close the second switch, and close the at least one switch.
30. The system of clause 29, wherein the control circuit is configured to, in a third configuration, cause the first input switching network to couple the transmit circuit to the first port of the first input hybrid coupler, cause the second input switching network to couple the transmit circuit to the second port of the second input hybrid coupler, close the first switch, close the second switch, and open the at least one switch.
31. The system of clause 26, further comprising:
   a first antenna coupled to the third port of the first output hybrid coupler; and
   a second antenna coupled to the fourth port of the second output hybrid coupler.
32. The system of clause 31, wherein the fourth port of the first output hybrid coupler is coupled to the third port of the second output hybrid coupler.
33. The system of any one of clauses 20 to 32, wherein the transmit circuit is configured to:
   output a first radio frequency (RF) signal to the first input switching network; and
   output a second RF signal to the second input switching network.
34. The system of any one of clauses 20 to 33, wherein the transmit circuit comprises:
   a splitter having an input, a first output, and a second output, wherein the splitter is configured to receive a radio frequency (RF) signal at the input of the splitter and split the RF signal between the first output of the splitter and the second output of the splitter, and wherein the first input switching network is coupled to the first output of the splitter; and
   a phase shifter coupled between the second output of the splitter and the second input switching network.
35. A method for wireless communications in a system, the system including a first amplifier, a second amplifier, a first output hybrid coupler having a first port coupled to an output of the first amplifier and a second port coupled to an output of the second amplifier, a third amplifier, a fourth amplifier, and a second output hybrid coupler having a first port coupled to an output of the third amplifier and a second port coupled to an output of the fourth amplifier, the method comprising:
   in a first configuration, coupling a third port of the first output hybrid coupler to a first antenna, coupling a fourth port of the first output hybrid coupler to a first termination load or a ground, coupling a third port of the second output hybrid coupler to a second antenna, and coupling a fourth port of the second output hybrid coupler to a second termination load or the ground; and
   in a second configuration, coupling the third port of the first output hybrid coupler to the first antenna or the second antenna, and coupling the third port of the second output hybrid coupler to the fourth port of the first output hybrid coupler.
36. The method of clause 35, further comprising, in the second configuration, coupling the fourth port of the second output hybrid coupler to the second termination load.
37. The method of clause 35 or 36, wherein the system further comprises a first input hybrid coupler having a first port, a second port coupled to a third termination load, a third port coupled to an input of the first amplifier, and the fourth port coupled to an input of the second amplifier, and a second input hybrid coupler having a first port, a second port coupled to a fourth termination load, a third port coupled to an input of the third amplifier, and a fourth port coupled to an input of the fourth amplifier.
38. The method of clause 37, further comprising:
   inputting a first radio frequency (RF) signal to the first port of the first input hybrid coupler; and inputting a second RF signal to the first port of the second input hybrid coupler.
39. The method of clause 38, wherein the second RF signal comprises a phase-shifted version of the first RF signal.
40. A method for wireless communications in a system, the system including a first amplifier, a second amplifier, a first input hybrid coupler having a first port, a second port, a third port coupled to an input of the first amplifier, and a fourth port coupled to an input of the second amplifier, a third amplifier, a fourth amplifier, and a second input hybrid coupler having a first port, a second port, a third port coupled to an input of the third amplifier, and a fourth port coupled to an input of the fourth amplifier, the method comprising:
   in a first configuration, inputting a first radio frequency (RF) signal to the first port of the first input hybrid coupler, coupling the second port of the first input hybrid coupler to a first termination load, inputting a second input RF signal to the first port of the second input hybrid coupler, and coupling the second port of the second input hybrid coupler to a second termination load; and
   in a second configuration, inputting the first RF signal to the second port of the first input hybrid coupler, coupling the first port of the first input hybrid coupler to the first termination load, inputting the second input RF signal to the second port of the second input hybrid coupler, and coupling the first port of the second input hybrid coupler to the second termination load.
41. The method of clause 40, further comprising, in a third configuration, inputting the first RF signal to the first port of the first input hybrid coupler, coupling the second port of the first input hybrid coupler to the first termination load, inputting the second input RF signal to the second port of the second input hybrid coupler, and coupling the first port of the second input hybrid coupler to the second termination load.
42. The method of clause 40 or 41, wherein the system further comprises a first output hybrid coupler having a first port coupled to an output of the first amplifier and a second port coupled to an output of the second amplifier, and a second output hybrid coupler having a first port coupled to an output of the third amplifier and a second port coupled to an output of the fourth amplifier.
43. The method of clause 42, further comprising:
   in the first configuration, coupling the third port of the first output hybrid coupler to a first antenna, and coupling the third port of the second output hybrid coupler to the fourth port of the first output hybrid coupler; and
   in the second configuration, coupling the fourth port of the second output hybrid coupler to a second antenna, and coupling the third port of the second output hybrid coupler to the fourth port of the first output hybrid coupler.
44. The method of clause 43, further comprising, in a third configuration, inputting the first RF signal to the first port of the first input hybrid coupler, coupling the second port of the first input hybrid coupler to the first termination load, inputting the second input RF signal to the second port of the second input hybrid coupler, coupling the first port of the second input hybrid coupler to the second termination load, coupling the third port of the first output hybrid coupler to the first antenna, and coupling the fourth port of the second output hybrid coupler to the second antenna.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that the term “ground” may refer to a DC ground or an AC ground, and thus the term “ground” covers both possibilities. It is also to be appreciated that an “inductor” may include multiple inductors coupled in series. It is also to be appreciated than an “input” may be a single-ended input, a differential input, or one of two inputs of a differential input, and an “output” may be a single-ended output, a differential output, or one of two outputs of a differential output. The term “approximately” means within a range of between 90 percent and 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A system, comprising:
a first amplifier;
a second amplifier;
a first output hybrid coupler having a first port, a second port, a third port, and a fourth port, wherein the first port of the first output hybrid coupler is coupled to an output of the first amplifier, and the second port of the first output hybrid coupler is coupled to an output of the second amplifier;
a third amplifier;
a fourth amplifier;
a second output hybrid coupler having a first port, a second port, a third port, and a fourth port, wherein the first port of the second output hybrid coupler is coupled to an output of the third amplifier, and the second port of the second output hybrid coupler is coupled to an output of the fourth amplifier; and
a switching network coupled between the fourth port of the first output hybrid coupler and the third port of the second output hybrid coupler.

2. The system of claim 1, wherein the third port of the first output hybrid coupler is coupled to a first antenna, and the fourth port of the second output hybrid coupler is coupled to a first termination load or a ground.

3. The system of claim 2, wherein the switching network comprises:
a first switch coupled between the fourth port of the first output hybrid coupler and a second termination load or between the forth port of the first output hybrid coupler and the ground;
a second switch coupled between the third port of the second output hybrid coupler and a second antenna; and
at least one switch coupled between the fourth port of the first output hybrid coupler and the third port of the second output hybrid coupler.

4. The system of claim 3, further comprising a control circuit configured to:
in a first configuration, close the first switch, close the second switch, and open the at least one switch; and
in a second configuration, open the first switch, open the second switch, and close the at least one switch.

5. The system of claim 4, wherein, in the first configuration, the first amplifier and the second amplifier operate as a first balanced amplifier, and the third amplifier and the fourth amplifier operate as a second balanced amplifier.

6. The system of claim 4, wherein, in the first configuration, the first amplifier and the second amplifier operate as a first Doherty amplifier, and the third amplifier and the fourth amplifier operate as a second Doherty amplifier.

7. The system of claim 1, further comprising an antenna select switch, wherein the third port of the first output hybrid coupler is coupled to the antenna select switch, the fourth port of the second output hybrid coupler is coupled to a first termination load or a ground, and the antenna select switch is configured to selectively couple the third port of the first output hybrid coupler to a first antenna or a second antenna.

8. The system of claim 7, wherein the switching network comprises:
a first switch coupled between the fourth port of the first output hybrid coupler and a second termination load or between the forth port of the first output hybrid coupler and the ground;
a second switch coupled between the third port of the second output hybrid coupler and the antenna select switch; and
at least one switch coupled between the fourth port of the first output hybrid coupler and the third port of the second output hybrid coupler.

9. The system of claim 8, further comprising a control circuit configured to:
in a first configuration, close the first switch, close the second switch, and open the at least one switch; and
in a second configuration, open the first switch, open the second switch, and close the at least one switch.

10. The system of claim 9, wherein, in the first configuration, the antenna select switch is configured to selectively couple the third port of the second output hybrid coupler to the first antenna or the second antenna.

11. The system of claim 1, further comprising:
a transmit circuit;
a first input hybrid coupler having a first port, a second port, a third port, and a fourth port, wherein the first port of the first input hybrid coupler is coupled to the transmit circuit, the third port of the first input hybrid coupler is coupled to an input of the first amplifier, and the fourth port of the first input hybrid coupler is coupled to an input of the second amplifier; and
a second input hybrid coupler having a first port, a second port, a third port, and a fourth port, wherein the first port of the second input hybrid coupler is coupled to the transmit circuit, the third port of the second input hybrid coupler is coupled to an input of the third amplifier, and the fourth port of the second input hybrid coupler is coupled to an input of the fourth amplifier.

12. The system of claim 11, further comprising:
a first termination load coupled the second port of the first input hybrid coupler; and
a second termination load coupled to the second port of the second input hybrid coupler.

13. The system of claim 11, wherein the transmit circuit is configured to:
output a first radio frequency (RF) signal to the first port of the first input hybrid coupler; and
output a second RF signal to the first port of the second input hybrid coupler.

14. The system of claim 13, wherein the transmit circuit comprises:
a splitter having an input, a first output, and a second output, wherein the splitter is configured to receive a radio frequency (RF) signal at the input of the splitter and split the RF signal between the first output of the splitter and the second output of the splitter, and wherein the first port of the first input hybrid coupler is coupled to the first output of the splitter; and
a phase shifter coupled between the second output of the splitter and the first port of the second input hybrid coupler.

15. The system of claim 1, further comprising:
a transmit circuit;
a first input hybrid coupler having a first port, a second port, a third port, and a fourth port, wherein the third port of the first input hybrid coupler is coupled to an input of the first amplifier, and the fourth port of the first input hybrid coupler is coupled to an input of the second amplifier;
a first input switching network coupled to the transmit circuit, the first port of the first input hybrid coupler, and the second port of the first input hybrid coupler, wherein the first input switching network is configured to selectively couple the transmit circuit to the first port of the first input hybrid coupler or the second port of the first input hybrid coupler;
a second input hybrid coupler having a first port, a second port, a third port, and a fourth port, wherein the third port of the second input hybrid coupler is coupled to an input of the third amplifier, and the fourth port of the second input hybrid coupler is coupled to an input of the fourth amplifier; and
a second input switching network coupled to the transmit circuit, the first port of the second input hybrid coupler, and the second port of the second input hybrid coupler, wherein the second input switching network is configured to selectively couple the transmit circuit to the first port of the second input hybrid coupler or the second port of the second input hybrid coupler.

16. The system of claim 15, further comprising:
a first switch coupled between the third port of the first output hybrid coupler and a first antenna; and
a second switch coupled between the fourth port of the second output hybrid coupler and a second antenna.

17. The system of claim 16, further comprising a control circuit configured to:
in a first configuration, cause the first input switching network to couple the transmit circuit to the first port of the first input hybrid coupler, cause the second input switching network to couple the transmit circuit to the first port of the second input hybrid coupler, close the first switch, and open the second switch; and
in a second configuration, cause the first input switching network to couple the transmit circuit to the second port of the first input hybrid coupler, cause the second input switching network to couple the transmit circuit to the second port of the second input hybrid coupler, open the first switch, and close the second switch.

18. The system of claim 17, wherein the switching network comprises at least one switch coupled between the third port of the second output hybrid coupler and the fourth port of the first output hybrid coupler, and the control circuit is configured to:
in the first configuration and the second configuration, close the at least one switch; and
in a third configuration, cause the first input switching network to couple the transmit circuit to the first port of the first input hybrid coupler, cause the second input switching network to couple the transmit circuit to the second port of the second input hybrid coupler, close the first switch, close the second switch, and open the at least one switch.

19. A system, comprising:
a transmit circuit;
a first amplifier;
a second amplifier;
a first input hybrid coupler having a first port, a second port, a third port, and a fourth port, wherein the third port of the first input hybrid coupler is coupled to an input of the first amplifier, and the fourth port of the first input hybrid coupler is coupled to an input of the second amplifier;
a first input switching network coupled to the transmit circuit, the first port of the first input hybrid coupler, and the second port of the first input hybrid coupler, wherein the first input switching network is configured to selectively couple the transmit circuit to the first port of the first input hybrid coupler or the second port of the first input hybrid coupler;
a third amplifier;
a fourth amplifier;
a second input hybrid coupler having a first port, a second port, a third port, and a fourth port, wherein the third port of the second input hybrid coupler is coupled to an input of the third amplifier, and the fourth port of the second input hybrid coupler is coupled to an input of the fourth amplifier; and
a second input switching network coupled to the transmit circuit, the first port of the second input hybrid coupler, and the second port of the second input hybrid coupler, wherein the second input switching network is configured to selectively couple the transmit circuit to the first port of the second input hybrid coupler or the second port of the second input hybrid coupler.

20. The system of claim 19, further comprising a first termination load coupled to the first input switching network, wherein the first input switching network is configured to selectively couple the first termination load to the first port of the first input hybrid coupler or the second port of the first input hybrid coupler.

21. The system of claim 20, further comprising a control circuit configured to:
in a first configuration, cause the first input switching network to couple the transmit circuit to the first port of the first input hybrid coupler and couple the first termination load to the second port of the first input hybrid coupler; and
in a second configuration, cause the first input switching network to couple the transmit circuit to the second port of the first input hybrid coupler and couple the first termination load to the first port of the first input hybrid coupler.

22. The system of claim 20, further comprising a second termination load coupled to the second input switching network, wherein the second input switching network is configured to selectively couple the second termination load to the first port of the second input hybrid coupler or the second port of the second input hybrid coupler.

23. The system of claim 22, further comprising a control circuit configured to:
in a first configuration, cause the first input switching network to couple the transmit circuit to the first port of the first input hybrid coupler and couple the first termination load to the second port of the first input hybrid coupler;
in the first configuration, cause the second input switching network to couple the transmit circuit to the first port of the second input hybrid coupler and couple the second termination load to the second port of the second input hybrid coupler;
in a second configuration, cause the first input switching network to couple the transmit circuit to the second port of the first input hybrid coupler and couple the first termination load to the first port of the first input hybrid coupler; and
in the second configuration, cause the second input switching network to couple the transmit circuit to the second port of the second input hybrid coupler and couple the second termination load to the first port of the second input hybrid coupler.

24. The system of claim 23, wherein the control circuit is further configured to:
in a third configuration, cause the first input switching network to couple the transmit circuit to the first port of the first input hybrid coupler and couple the first termination load to the second port of the first input hybrid coupler; and
in the third configuration, cause the second input switching network to couple the transmit circuit to the second port of the second input hybrid coupler and couple the second termination load to the first port of the second input hybrid coupler.

25. The system of claim 19, further comprising:
a first output hybrid coupler having a first port, a second port, a third port, and a fourth port, wherein the first port of the first output hybrid coupler is coupled to an output of the first amplifier, and the second port of the first output hybrid coupler is coupled to an output of the second amplifier; and
a second output hybrid coupler having a first port, a second port, a third port, and a fourth port, wherein the first port of the second output hybrid coupler is coupled to an output of the third amplifier, the second port of the second output hybrid coupler is coupled to an output of the fourth amplifier.

26. The system of claim 25, further comprising:
a first switch coupled between the third port of the first output hybrid coupler and a first antenna; and
a second switch coupled between the fourth port of the second output hybrid coupler and a second antenna.

27. The system of claim 26, further comprising at least one switch coupled between the third port of the second output hybrid coupler and the fourth port of the first output hybrid coupler.

28. The system of claim 27, further comprising a control circuit configured to:
in a first configuration, cause the first input switching network to couple the transmit circuit to the first port of the first input hybrid coupler, cause the second input switching network to couple the transmit circuit to the first port of the second input hybrid coupler, close the first switch, open the second switch, and close the at least one switch; and
in a second configuration, cause the first input switching network to couple the transmit circuit to the second port of the first input hybrid coupler, cause the second input switching network to couple the transmit circuit to the second port of the second input hybrid coupler, open the first switch, close the second switch, and close the at least one switch.

29. The system of claim 28, wherein the control circuit is configured to, in a third configuration, cause the first input switching network to couple the transmit circuit to the first port of the first input hybrid coupler, cause the second input switching network to couple the transmit circuit to the second port of the second input hybrid coupler, close the first switch, close the second switch, and open the at least one switch.

30. The system of claim 19, wherein the transmit circuit comprises:
a splitter having an input, a first output, and a second output, wherein the splitter is configured to receive a radio frequency (RF) signal at the input of the splitter and split the RF signal between the first output of the splitter and the second output of the splitter, and wherein the first input switching network is coupled to the first output of the splitter; and
a phase shifter coupled between the second output of the splitter and the second input switching network.
